(19) United States
(12) Patent Application Publication
(10) Pub. No.: US 2026/0074664 A1
(43) Pub. Date: Mar. 12, 2026

(54) VOLTAGE GENERATION CIRCUIT

(71) Applicant: Panasonic Automotive Systems Co., Ltd., Kanagawa (JP)

(72) Inventor: Takahiro HAYAKAWA, Kanagawa (JP)

(73) Assignee: Panasonic Automotive Systems Co., Ltd., Kanagawa (JP)

(21) Appl. No.: 19/307,852

(22) Filed: Aug. 22, 2025

(30) Foreign Application Priority Data
Sep. 11, 2024 (JP) 2024-157809

(51) Int. Cl. H03F 3/45; H03K 17/687

(52) U.S. Cl. CPC H03F 3/45475; H03K 17/6871

(57) ABSTRACT

A voltage generation circuit includes a voltage input terminal to which an input voltage is input, a voltage output terminal from which an output voltage is output, a first resistor including a first terminal electrically connected to the voltage input terminal and a second terminal electrically connected to the voltage output terminal, a second resistor including a third terminal electrically connected to the second terminal and a fourth terminal, a first capacitor electrically connected to one of the first terminal and the second terminal, and a first circuit electrically connected to the one of the first terminal and the second terminal and including a charging circuit configured to charge the first capacitor.

### TECHNICAL FIELD

The present disclosure relates to a voltage generation circuit.

### BACKGROUND ART

In the related art, a voltage generation circuit that generates a predetermined voltage is known. As the voltage generation circuit, a differential amplification device in Patent Literature 1 is known. In the differential amplification device, a power supply voltage Vcc by a series circuit of a resistor 2 and a resistor 3, and a voltage across the resistor 3 is stabilized by a capacitor 4.

### CITATION LIST

### Patent Literature

Patent Literature 1: JPH01-200708A

### SUMMARY OF INVENTION

In the differential amplification device in Patent Literature 1, when an output voltage is generated by using a capacitor, it is difficult to quickly stabilize the output voltage while reducing noise, and there is room for improvement.

The present disclosure provides a voltage generation circuit in which an output voltage can be quickly stabilized while reducing noise even when the output voltage is generated by using a capacitor.

A aspect of the present disclosure is a voltage generation circuit including a voltage input terminal to which an input voltage is input; a voltage output terminal from which an output voltage is output, a first resistor including a first terminal electrically connected to the voltage input terminal and a second terminal electrically connected to the voltage output terminal, a second resistor including a third terminal electrically connected to the second terminal and a fourth terminal, a first capacitor electrically connected to one of the first terminal and the second terminal, and a first circuit electrically connected to the one of the first terminal and the second terminal and including a charging circuit configured to charge the first capacitor.

According to the present disclosure, an output voltage can be quickly stabilized while reducing noise even when the output voltage is generated by using a capacitor.

### BRIEF DESCRIPTION OF DRAWINGS

FIG. 1 is a diagram illustrating a configuration of a voltage generation circuit according to a comparative example;

FIG. 2A is a diagram illustrating a change in an input voltage and a change in a voltage at a point A of the voltage generation circuit according to the comparative example;

FIG. 2B is a diagram illustrating a current flowing from a resistor R20 to a capacitor C20 of the voltage generation circuit according to the comparative example;

FIG. 2C is a diagram illustrating a relation between a gain and a frequency of the voltage generation circuit according to the comparative example;

FIG. 3A is a diagram illustrating a first example of a configuration of a voltage generation circuit according to an embodiment of the present disclosure;

FIG. 3B is a diagram illustrating a second example of the configuration of the voltage generation circuit;

FIG. 4 is a diagram illustrating voltages at respective points in the voltage generation circuit;

FIG. 5A is a diagram illustrating a voltage at a voltage input terminal and a voltage at a voltage output terminal of the voltage generation circuit according to the comparative example;

FIG. 5B is a diagram illustrating an amplitude spectrum of the voltage at the voltage input terminal and an amplitude spectrum of the voltage at the voltage output terminal of the voltage generation circuit according to the comparative example;

FIG. 6A is a diagram illustrating a comparison between a voltage at a voltage input terminal and a voltage at a voltage output terminal of the voltage generation circuit according to the embodiment;

FIG. 6B is a diagram illustrating an amplitude spectrum of the voltage at the voltage input terminal and an amplitude spectrum of the voltage at the voltage output terminal of the voltage generation circuit according to the embodiment;

FIG. 7 is a diagram illustrating a configuration of a voltage generation circuit in a case in which an FET is used as a transistor;

FIG. 8 is a diagram illustrating a case in which the voltage generation circuit includes a bias power supply circuit and an additional circuit;

FIG. 9 is a diagram illustrating a change in the voltage at the point A of the voltage generation circuit according to the comparative example in a case in which a capacitor C20 has a capacitance value of 220 μF and a change in a voltage at a point A of the voltage generation circuit according to the embodiment in a case in which a capacitor C1 has a capacitance value of 2200 μF;

FIG. 10 is a diagram comparing information regarding a resistor R3;

FIG. 11 is a diagram illustrating a characteristic of a charging current from the resistor R3 to a capacitor C1;

FIG. 12 is a diagram illustrating a charging waveform and an equivalent rectangular waveform of the charging current of the capacitor C1;

FIG. 13 is a diagram illustrating a charging waveform and an equivalent rectangular waveform of the capacitor C1 until the charging current reaches 0.5 Ip;

FIG. 14 is a table illustrating a relation between an output voltage/input voltage and a reduction coefficient;

FIG. 15A is a diagram illustrating a dead voltage;

FIG. 15B is a diagram illustrating a time Toffon for turning on a power supply again;

FIG. 16 is a diagram illustrating the output voltage in a case in which a positive voltage is output from a positive power supply in the voltage generation circuit;

FIG. 17A is a diagram illustrating a configuration of the voltage generation circuit in a case in which a negative voltage is output from a negative power supply in the voltage generation circuit;

FIG. 17B is a diagram illustrating the output voltage of the voltage generation circuit in the case in which the negative voltage is output from the negative power supply in the voltage generation circuit;

FIG. 18A is a diagram illustrating a configuration of the voltage generation circuit in a case in which the voltage generation circuit serving as a dual power supply circuit outputs the positive voltage;

FIG. 18B is a diagram illustrating the output voltage of the voltage generation circuit in the case in which the voltage generation circuit serving as the dual power supply circuit outputs the positive voltage;

FIG. 19A is a diagram illustrating a configuration of the voltage generation circuit in the another case in which the voltage generation circuit serving as the dual power supply circuit outputs the positive voltage;

FIG. 19B is a diagram illustrating the output voltage of the voltage generation circuit in the another case in which the voltage generation circuit serving as the dual power supply circuit outputs the positive voltage;

FIG. 20A is a diagram illustrating a configuration of the voltage generation circuit in a case in which the voltage generation circuit serving as a negative power supply circuit outputs the negative voltage;

FIG. 20B is a diagram illustrating the output voltage of the voltage generation circuit in the case in which the voltage generation circuit serving as the negative power supply circuit outputs the negative voltage;

FIG. 21A is a diagram illustrating a configuration of the voltage generation circuit in a case in which the voltage generation circuit serving as the dual power supply circuit outputs the negative voltage;

FIG. 21B is a diagram illustrating the output voltage of the voltage generation circuit in the case in which the voltage generation circuit serving as the dual power supply circuit outputs the negative voltage;

FIG. 22A is a diagram illustrating a configuration of the voltage generation circuit in a case in which the safety at the time of failure is further improved in the voltage generation circuit;

FIG. 22B is a diagram illustrating the output voltage of the voltage generation circuit in the case in which the safety at the time of failure is further improved in the voltage generation circuit;

FIG. 23A is a diagram illustrating configurations of the voltage generation circuit and a peripheral circuit thereof in a case in which the voltage generation circuit is applied to a regulator output;

FIG. 23B is a diagram illustrating voltages and currents at respective positions of the voltage generation circuit and the peripheral circuit thereof in the case in which the voltage generation circuit is applied to the regulator output;

FIG. 24A is a diagram illustrating a configuration of the voltage generation circuit in a case in which the voltage generation circuit includes an operational amplifier terminal protection circuit;

FIG. 24B is a diagram illustrating the output voltage of the voltage generation circuit in the case in which the voltage generation circuit includes the operational amplifier terminal protection circuit;

FIG. 25A is a diagram illustrating a configuration of the voltage generation circuit in a case in which the voltage generation circuit includes a microcomputer-controlled reset circuit;

FIG. 25B is a diagram illustrating voltages at respective positions of the voltage generation circuit in the case in which the voltage generation circuit includes the microcomputer-controlled reset circuit;

FIG. 26A is a diagram illustrating a configuration of the voltage generation circuit in a case in which the voltage generation circuit includes an automatic reset circuit;

FIG. 26B is a diagram illustrating voltages at respective positions of the voltage generation circuit in the case in which the voltage generation circuit includes the automatic reset circuit;

FIG. 27A is a diagram illustrating a state in which a power supply is turned off in a case in which the voltage generation circuit includes the automatic reset circuit, and is a diagram illustrating a circuit in which a part of the voltage generation circuit is extracted;

FIG. 27B is a diagram illustrating the state in which the power supply is turned off in the case in which the voltage generation circuit includes the automatic reset circuit, and is a diagram illustrating voltages and currents at respective positions of the voltage generation circuit;

FIG. 28 is a diagram illustrating a state in which the power supply is turned on in the case in which the voltage generation circuit includes the automatic reset circuit, and is a diagram illustrating voltages and currents at respective positions of the voltage generation circuit;

FIG. 29A is a diagram illustrating a configuration of the voltage generation circuit in a case in which the voltage generation circuit includes a microcomputer-controlled discharge circuit;

FIG. 29B is a diagram illustrating voltages at respective positions of the voltage generation circuit in the case in which the voltage generation circuit includes the microcomputer-controlled discharge circuit;

FIG. 30A is a diagram illustrating a configuration of the voltage generation circuit in a case in which the voltage generation circuit includes an automatic discharge circuit;

FIG. 30B is a diagram illustrating voltages at respective positions of the voltage generation circuit in the case in which the voltage generation circuit includes the automatic discharge circuit;

FIG. 31 is a diagram illustrating a configuration of the voltage generation circuit in another case in which the voltage generation circuit includes the automatic discharge circuit;

FIG. 32 is a diagram illustrating voltages at respective positions of the voltage generation circuit in the another case in which the voltage generation circuit includes the automatic discharge circuit;

FIG. 33 is a diagram illustrating a configuration of a voltage generation circuit in a case in which the voltage generation circuit includes the microcomputer-controlled reset circuit;

FIG. 34 is a diagram illustrating a configuration of the voltage generation circuit in a case in which the voltage generation circuit includes the microcomputer-controlled discharge circuit;

FIG. 35 is a diagram illustrating a configuration of the voltage generation circuit in a case in which the voltage generation circuit includes a microcomputer-controlled discharge circuit;

FIG. 36 is a diagram illustrating a configuration of the voltage generation circuit in a case in which the voltage generation circuit includes an automatic discharge circuit;

FIG. 37 is a diagram illustrating a configuration of the voltage generation circuit in another case in which the voltage generation circuit includes an automatic discharge circuit;

FIG. 38 is a diagram illustrating an input voltage in a case in which the voltage generation circuit includes an automatic discharge circuit K7A and an input voltage in a case in which the voltage generation circuit includes an automatic discharge circuit K7B; and

FIG. 39 is a diagram illustrating an output voltage Vout in the case in which the voltage generation circuit includes the automatic discharge circuit K7A, the output voltage Vout in the case in which the voltage generation circuit includes the automatic discharge circuit K7B, and the output voltage Vout in a case in which the voltage generation circuit does not include the automatic discharge circuit.

### DESCRIPTION OF EMBODIMENTS

Hereinafter, embodiments specifically disclosing a voltage generation circuit according to the present disclosure will be described in detail with reference to the drawings as appropriate. However, unnecessarily detailed description may be omitted. For example, the detailed description of well-known matters and the redundant description of substantially the same configuration may be omitted. This is to avoid unnecessary redundancy of the following description and to facilitate understanding of a person skilled in the art. It should be noted that the accompanying drawings and the following description are provided for a person skilled in the art to fully understand the present disclosure, and are not intended to limit the subject matter described in the claims.

### Findings as Basis of Present Disclosure

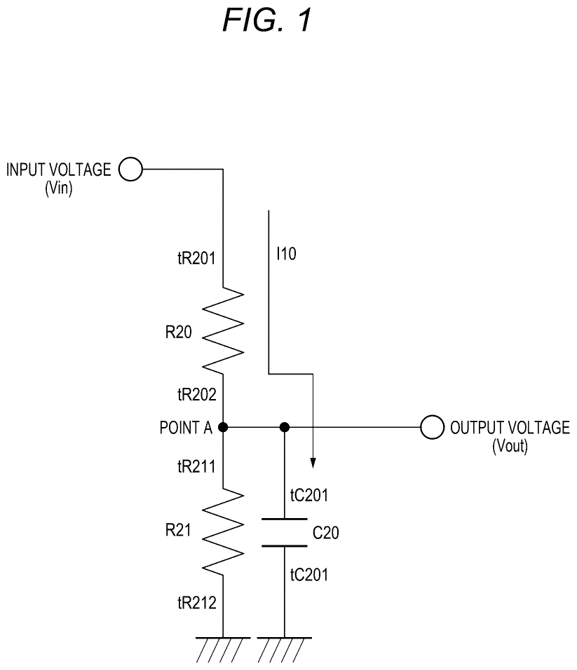

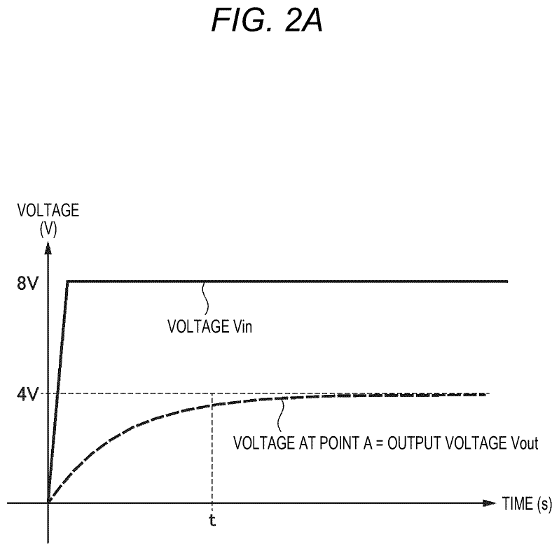

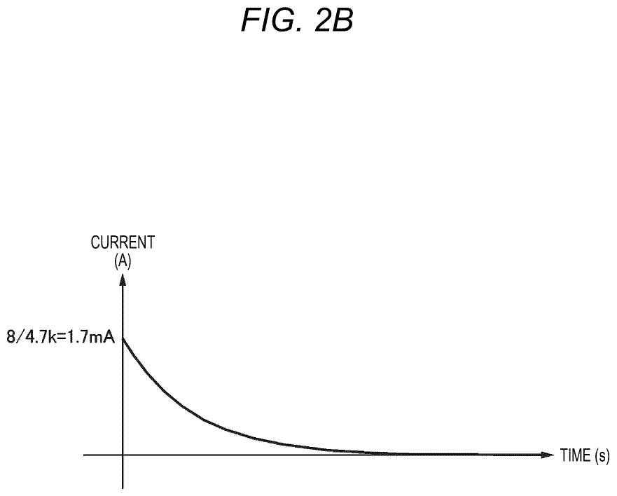

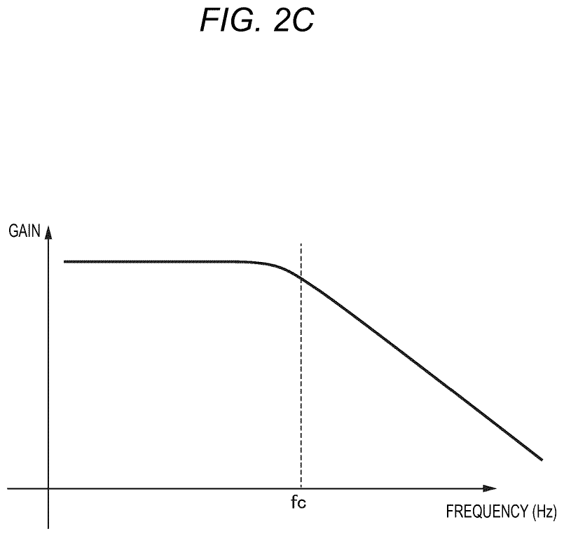

FIG. 1 is a diagram illustrating a configuration of a voltage generation circuit 1X as a comparative example. FIG. 2A is a diagram illustrating a change in an input voltage and a change in a voltage at a point A of the voltage generation circuit 1X. FIG. 2B is a diagram illustrating a current flowing from a resistor R20 to a capacitor C20 of the voltage generation circuit 1X. FIG. 2C is a diagram illustrating a relation between a gain and a frequency of the voltage generation circuit 1X.

The voltage generation circuit 1X includes a resistor R20, a resistor R21, and a capacitor C20. The resistor R20 includes a terminal tR201 and a terminal tR202. The resistor R21 includes a terminal tR211 and a terminal tR212. The capacitor C20 includes a terminal tC201 and a terminal tC202. The terminal tR202, the terminal tR211, and the terminal tC201 are connected at the point A. The input voltage Vin is, for example, 8 V. A resistance value of the resistor R20 and a resistance value of the resistor R21 are equal to each other and are, for example, 4.7 k≤2. In this case, the input voltage Vin is divided by the resistor R20 and the resistor R21, and an output voltage Vout becomes 4 V.

As illustrated in FIG. 2A, the voltage at the point A in the voltage generation circuit 1X is the output voltage Vout, and changes more smoothly than the input voltage Vin. This is because an electric charge is supplied to the capacitor C20 via the resistor R20, and as illustrated in FIG. 2B, the supply of a current I10 from a power supply to the capacitor C20 is limited by the resistor R20. In order to reduce a time t required for the voltage at the point A to be stabilized, it is desirable to reduce a capacitance of the capacitor C20 and the resistance value of the resistor R20. This is because t=CR. On the other hand, as illustrated in FIG. 2C, the gain in the voltage generation circuit 1X decreases in a region in which a frequency is larger than a cutoff frequency fc. Therefore, in order to reduce noise, that is, the gain in the voltage generation circuit 1X, it is desirable to increase the capacitance of the capacitor C20 or the resistance value of the resistor R20 because the cutoff frequency fc is preferably small. This is because fc=½πCR. That is, there is a dilemma in which the time t required for the voltage at the point A to stabilize becomes longer when attempting to reduce the noise, and the noise increases when attempting to reduce the time t required for the voltage at the point A to stabilize.

In the following embodiment, a voltage generation circuit will be described in which an output voltage can be quickly stabilized while reducing noise even when the output voltage is generated by using a capacitor.

### EMBODIMENT

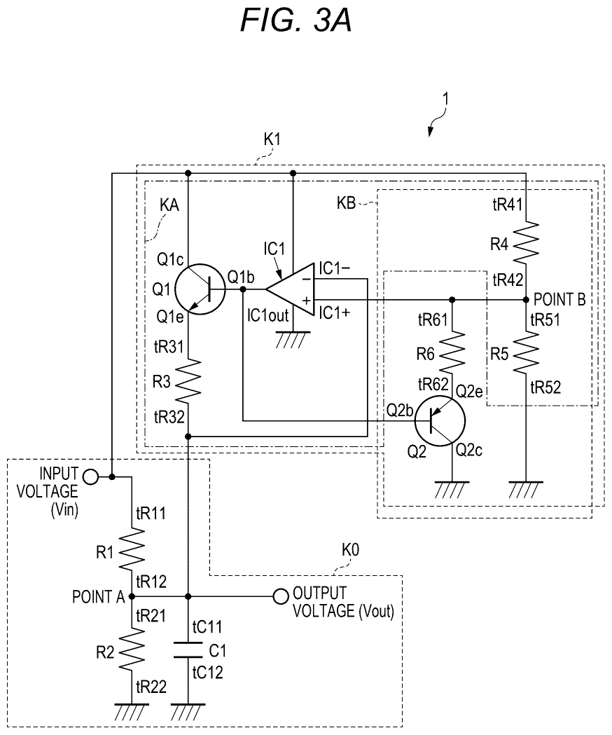

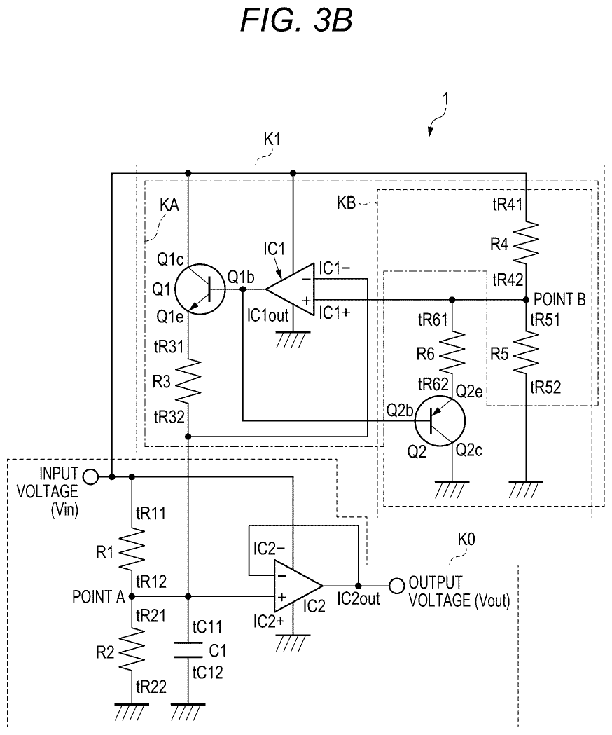

FIG. 3A is a diagram illustrating a first example of a configuration of a voltage generation circuit 1 according to the embodiment of the present disclosure. FIG. 3B is a diagram illustrating a second example of the configuration of the voltage generation circuit 1.

As illustrated in FIG. 3A, the voltage generation circuit 1 includes a voltage divider circuit K0 and an additional circuit K1. The voltage divider circuit K0 has the same configuration as the voltage generation circuit 1X.

Specifically, the voltage divider circuit K0 includes a voltage input terminal Vin, a voltage output terminal Vout, a resistor R1, a resistor R2, and a capacitor C1. The voltage input terminal Vin is a terminal to which an input voltage is input. The voltage output terminal Vout is a terminal from which an output voltage is output. The resistor R1 includes a terminal tR11 and a terminal tR12. The resistor R1 is an example of a first resistor. The resistor R2 includes a terminal tR21 and a terminal tR22. The resistor R2 is an example of a second resistor. The capacitor C1 includes a terminal tC11 and a terminal tC12. The capacitor C1 is an example of a first capacitor.

The terminal tR11 is electrically connected to the voltage input terminal Vin. The terminal tR11 is an example of a first terminal. The terminal tR12 is electrically connected to the terminal tR21, the terminal tC11, and the voltage output terminal Vout. The terminal tR12 is an example of a second terminal. The terminal tR21 is electrically connected to the terminal tR12, the terminal tC11, and the voltage output terminal Vout. The terminal tR22 is electrically connected to a ground potential, that is, ground. The terminal tC11 is electrically connected to the terminal tR21 and the voltage output terminal Vout. The terminal tC12 is electrically connected to a ground potential. A connection point between the resistor R1 and the resistor R2 is a point A.

The additional circuit K1 is a circuit added to the voltage divider circuit K0. The additional circuit K1 is an example of a first circuit. The additional circuit K1 includes at least a charging circuit KA. The additional circuit K1 may include a stop circuit KB. The charging circuit KA is a circuit that charges the capacitor C1. The stop circuit KB is a circuit that stops the charging of the charging circuit KA.

The charging circuit KA includes a resistor R4, a resistor R5, an operational amplifier IC1, a transistor Q1, and a resistor R3. The resistor R3 is an example of a fifth resistor. The transistor Q1 is an example of a first transistor. The transistor Q1 is, for example, an NPN bipolar transistor. The operational amplifier IC1 includes an inverting input terminal IC1−, a non-inverting input terminal IC1+, and an output terminal IC1out. The transistor Q1 includes a base terminal Q1b, a collector terminal Q1c, and an emitter terminal Q1e. The base terminal Q1b is an example of a first control terminal. The collector terminal Q1c is an example of a first non-control terminal. The emitter terminal Q1e is an example of a second non-control terminal. The resistor R3 includes a terminal tR31 and a terminal tR32. The terminal tR31 is an example of a ninth terminal. The terminal tR32 is an example of a tenth terminal. The inverting input terminal IC1−, the terminal tR32, the terminal tR12, the terminal tR21, the terminal tC11, and the voltage output terminal Vout are electrically connected. The base terminal Q1b and the output terminal IC1out are electrically connected. The collector terminal Q1c, a power supply terminal of the operational amplifier IC1, and the voltage input terminal Vin are electrically connected. The emitter terminal Q1e and the terminal tR31 are electrically connected.

The stop circuit KB includes a resistor R4, a resistor R5, a resistor R6, and a transistor Q2. The resistor R4 is an example of a third resistor. The resistor R5 is an example of a fourth resistor. The resistor R6 is an example of a sixth resistor. The transistor Q2 is an example of a second transistor. The transistor Q2 is, for example, a PNP bipolar transistor. The resistor R4 includes a terminal tR41 and a terminal tR42. The terminal tR41 is an example of a fifth terminal. The terminal tR42 is an example of a sixth terminal. The resistor R5 includes a terminal tR51 and a terminal tR52. The terminal tR51 is an example of a seventh terminal. The terminal tR52 is an example of an eighth terminal. The resistor R6 includes a terminal tR61 and a terminal tR62. The terminal tR61 is an example of an eleventh terminal. The terminal tR62 is an example of a twelfth terminal. The transistor Q2 includes a base terminal Q2b, a collector terminal Q2c, and an emitter terminal Q2e. The base terminal Q2b is an example of a second control terminal. The collector terminal Q2c is an example of a third non-control terminal. The emitter terminal Q2e is an example of a fourth non-control terminal.

The terminal tR41 and the voltage input terminal Vin are electrically connected. The terminal tR42, the terminal tR51, the terminal tR61, and the non-inverting input terminal IC1+ are electrically connected. A connection point between the resistor R4, the resistor R5, the non-inverting input terminal IC1+, and the like is a point B. The terminal tR52 is electrically connected to a ground potential. The base terminal Q2b, the output terminal IC1out, and the base terminal Q1b are electrically connected. The collector terminal Q2c is electrically connected to a ground potential. The emitter terminal Q2e is electrically connected to the terminal tR62.

In FIG. 3A, a resistance value of the resistor R1 is, for example, 4.7 (kΩ). A resistance value of the resistor R2 is, for example, 4.7 (kΩ). A resistance value of the resistor R3 is, for example, 200 (Ω). A resistance value of the resistor R4 is, for example, 4.7 (kΩ). A resistance value of the resistor R5 is, for example, 4.7 (kΩ). A resistance value of the resistor R6 is, for example, 4.7 (kΩ). A capacitance value of the capacitor C1 is, for example, 220 (μF). The specific resistance values and the capacitance value of these elements are examples. When the same elements are illustrated in other drawings, resistance values and a capacitance value of the same elements may be set to the same values as or different values from these resistance values and the capacitance value within a range intended in the embodiment.

The voltage generation circuit 1 in FIG. 3B additionally includes a voltage follower in the voltage generation circuit 1 in FIG. 3A. The voltage follower is a circuit that sets a power supply output to a low impedance output. The voltage follower includes an operational amplifier IC2. The operational amplifier IC2 includes an inverting input terminal IC2−, a non-inverting input terminal IC2+, and an output terminal IC2out. The inverting input terminal IC2−, the output terminal IC2out, and the voltage output terminal Vout are electrically connected. The non-inverting input terminal IC2+, the terminal tC11, the terminal tR12, the terminal tR21, the terminal tR32, and the inverting input terminal IC1− are electrically connected.

Next, operations of the voltage generation circuit 1 in FIG. 3A will be described. In this example, a voltage of 8 V is input to the voltage input terminal Vin.

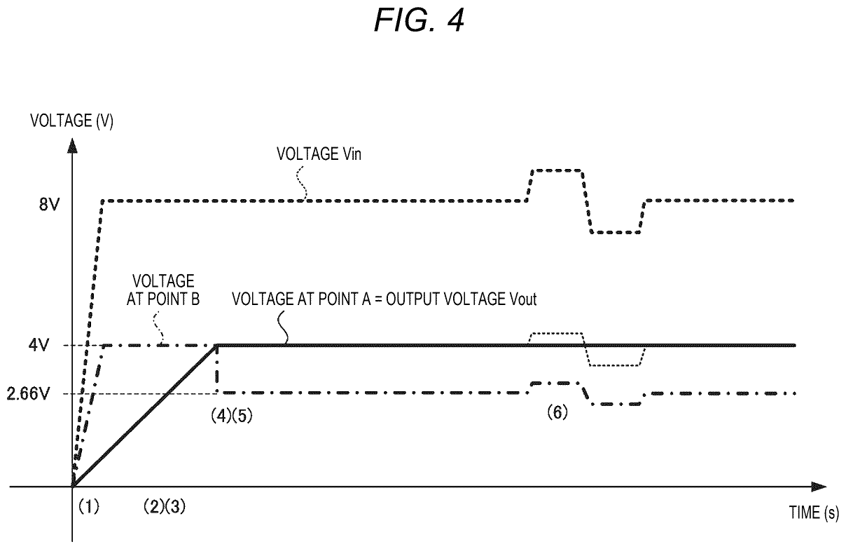

FIG. 4 is a diagram illustrating voltages at respective points in the voltage generation circuit 1. Timings of (1) to (5) in FIG. 4 indicate timings of operations of (1) to (5) described below.

First, (resistance value of resistor R1):(resistance value of resistor R2)=(resistance value of resistor R4):(resistance value of resistor R5) is set such that a voltage at the point A and a voltage at the point B are the same. Here, (resistance value of resistor R1):(resistance value of resistor R2)=(resistance value of resistor R4):(resistance value of resistor R5)=1:1.

(1)

As illustrated in FIG. 4, when an input voltage of 8 V is applied to the voltage input terminal Vin, the voltage at the point B is instantaneously stabilized at, for example, 4 V. This is because the voltage at the point B is not affected by the capacitor C1.

(2)

Next, the operational amplifier IC1 compares a voltage VA which is the voltage at the point A with a voltage VB which is the voltage at the point B. Since the voltage VB at the point B is larger than the voltage VA at the point A, the operational amplifier IC1 outputs a High voltage, for example, a voltage of 8 V as an output. When an output voltage of the operational amplifier IC1 is a High voltage, the transistor Q2 is turned off.

(3)

Then, the transistor Q1 is turned on, and an electric charge is supplied to the capacitor C1 via the resistor R3. In this case, the voltage at the point A rapidly rises as the resistance value of the resistor R3 decreases.

When the voltage at the point A rises, a voltage output from the voltage output terminal Vout also rises.

(4)

When the voltage at the point A rises and the voltage VA at the point A becomes larger than the voltage VB at the point B, the operational amplifier IC1 outputs a Low voltage, for example, a voltage of 0 V, from the output terminal IC1out. As a result, the transistor Q1 is turned off, and no electric charge is supplied to the capacitor C1.

(5)

The transistor Q2 is turned on when the Low voltage output from the output terminal IC1out is input to the base terminal Q2b of the transistor Q2. Accordingly, the point B is electrically connected to ground via the resistor R6 and the transistor Q2, and therefore, the voltage VB at the point B decreases. Accordingly, a state in which the voltage VA at the point A is larger than the voltage VB at the point B is easily maintained. During this period, the charging circuit KA does not operate.

That is, the operational amplifier IC1 compares a non-inverting input voltage input to the non-inverting input terminal IC1+ with an inverting input voltage input to the inverting input terminal IC1−. The non-inverting input voltage is a voltage at the non-inverting input terminal IC1+. The inverting input voltage is a voltage at the inverting input terminal IC1−. The operational amplifier IC1 outputs, from the output terminal IC1out, an on voltage for turning on the transistor Q1 when the non-inverting input voltage is smaller than the inverting input voltage. The operational amplifier IC1 outputs, from the output terminal IC1out, an off voltage for turning off the transistor Q1 when the non-inverting input voltage is larger than the inverting input voltage.

Even when the voltage VA at the point A and the voltage VB at the point B are once stabilized in a state in which the voltage VA at the point A is larger than the voltage VB at the point B, the voltage at the voltage input terminal Vin may fluctuate due to external noise, a connected device, or the like. For example, when the input voltage Vin fluctuates as illustrated in (6), the voltage VA at the point A and the voltage VB at the point B may also fluctuate. The voltage VB at the point B is more likely to fluctuate than the voltage VA at the point A due to an influence of the fluctuation of the input voltage Vin. Since the capacitor C1 is electrically connected to the point A, the voltage VA at the point A is relatively less likely to fluctuate. Therefore, a magnitude relation between the voltage VA at the point A and the voltage VB at the point B is likely to change due to the fluctuation of the input voltage Vin, and the output voltage of the operational amplifier IC1 may frequently change. As a result, the output voltage Vout may fluctuate. In the present embodiment, since the voltage generation circuit 1 includes the stop circuit KB, the state in which the voltage VA at the point A is larger than the voltage VB at the point B is easily maintained. Accordingly, in the voltage generation circuit 1, once the voltage at the voltage output terminal Vout stabilizes at a desired voltage, for example, 4 V, the voltage at the voltage output terminal Vout can be maintained stable. This series of operations is similar to that of the voltage generation circuit 1 in FIG. 3B.

Next, the performance of the voltage generation circuit 1 will be described.

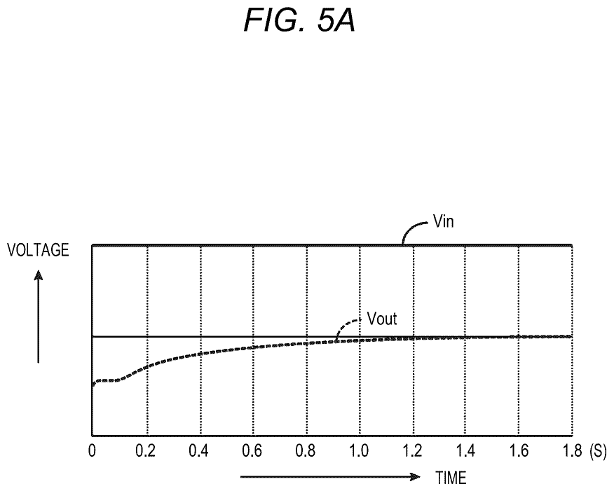

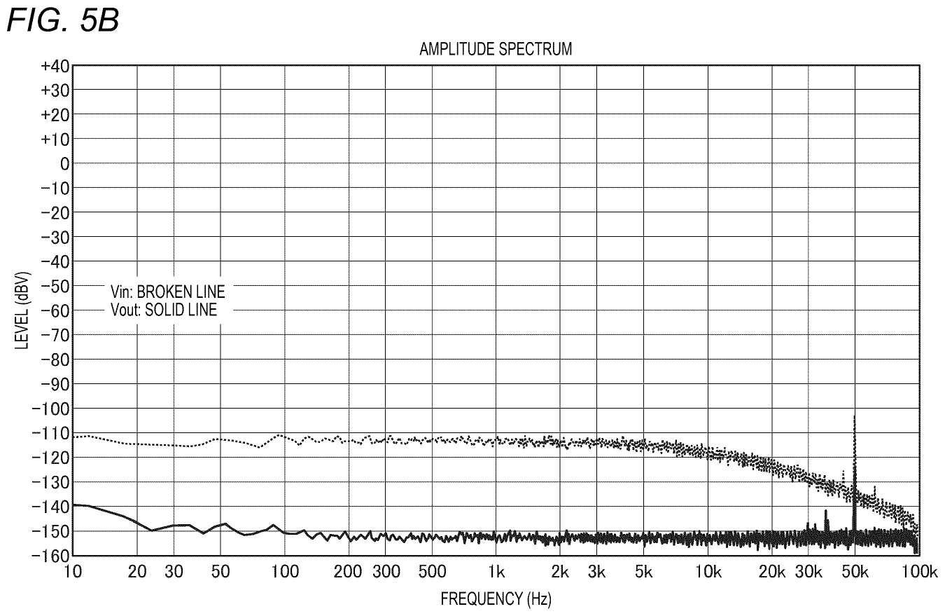

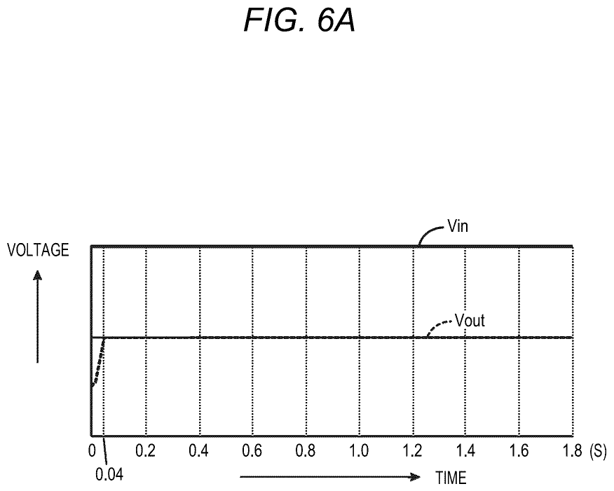

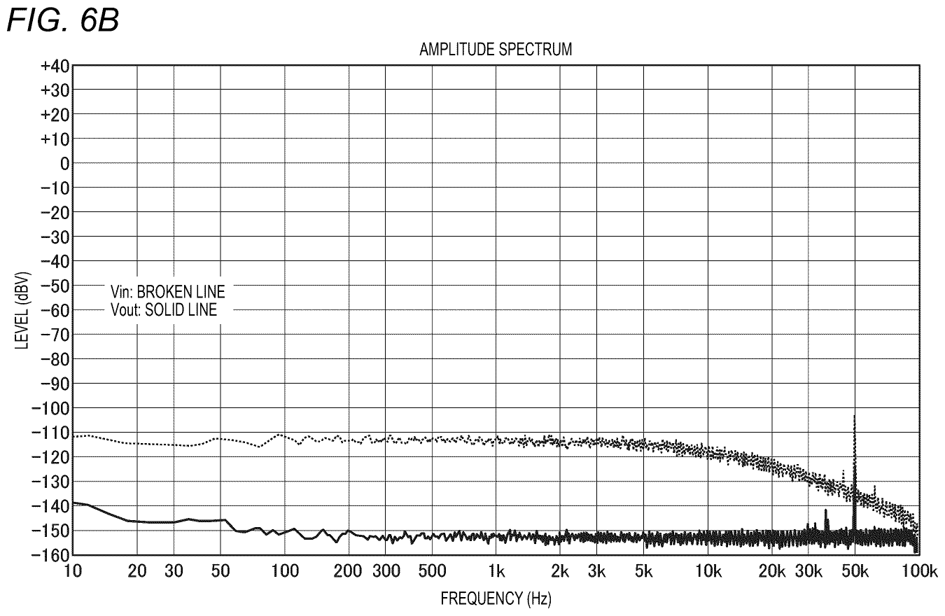

FIG. 5A is a diagram illustrating a voltage at a voltage input terminal Vin and a voltage at a voltage output terminal Vout of the voltage generation circuit 1X. FIG. 5B is a diagram illustrating an amplitude spectrum of the voltage at the voltage input terminal Vin and an amplitude spectrum of the voltage at the voltage output terminal Vout of the voltage generation circuit 1X. FIG. 6A is a diagram illustrating the voltage at the voltage input terminal Vin and the voltage at the voltage output terminal Vout of the voltage generation circuit 1. FIG. 6B is a diagram illustrating an amplitude spectrum of the voltage at the voltage input terminal Vin and an amplitude spectrum of the voltage at the voltage output terminal Vout of the voltage generation circuit 1.

As illustrated in FIG. 5A, in the voltage generation circuit 1X, it takes time to stabilize the voltage at the voltage output terminal Vout. Here, it takes, for example, about 1.8 seconds for the voltage to stabilize. On the other hand, as illustrated in FIG. 6A, in the voltage generation circuit 1, the voltage at the voltage output terminal Vout is quickly stabilized. Here, a time required for the voltage to stabilize is, for example, about 40 milliseconds. On the other hand, as illustrated in FIGS. 5B and 6B, in the voltage generation circuit 1X and the voltage generation circuit 1, there is almost no change in the amplitude spectrum of each voltage. That is, there is almost no change in an amount of noise contained in the voltage at each of the voltage input terminal Vin and the voltage output terminal Vout. Therefore, in the voltage generation circuit 1, the voltage at the voltage output terminal Vout can be quickly stabilized while effectively reducing the noise.

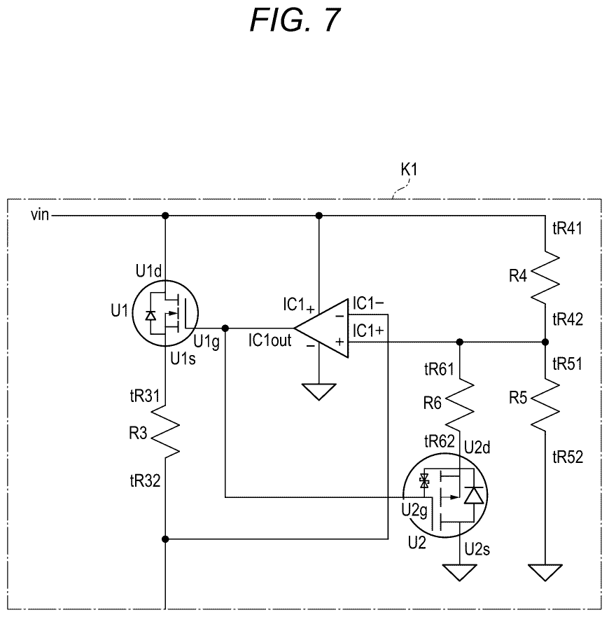

FIG. 7 is a diagram illustrating a configuration of a voltage generation circuit in a case in which an FET is used as a transistor.

As illustrated in FIG. 7, the transistor Q1 and the transistor Q2 in the voltage generation circuit 1 in FIG. 3A may be replaced with FETs, that is, field-effect transistors. FET is an abbreviation for field effect transistor.

The transistor Q1 may be replaced with a transistor U1 such that the base terminal Q1b, the collector terminal Q1c, and the emitter terminal Q1e of the transistor Q1 correspond to a gate terminal U1g, a drain terminal U1d, and a source terminal U1s of the transistor U1 that is a FET, respectively. The transistor U1 is, for example, an N-channel FET. The transistor Q2 may be replaced with a transistor U2 such that the base terminal Q2b, the collector terminal Q2c, and the emitter terminal Q2e of the transistor Q2 correspond to a gate terminal U2g, a drain terminal U2d, and a source terminal U2s of the transistor U2 that is a FET, respectively. The transistor U2 is, for example, a P-channel FET. Similarly, the transistor Q1 and the transistor Q2 in the voltage generation circuit 1 in FIG. 3B may be replaced with the transistor U1 and the transistor U2 which are the FET, respectively.

Next, a case in which the voltage generation circuit 1 includes a bias power supply circuit K2 instead of the voltage divider circuit K0 will be described.

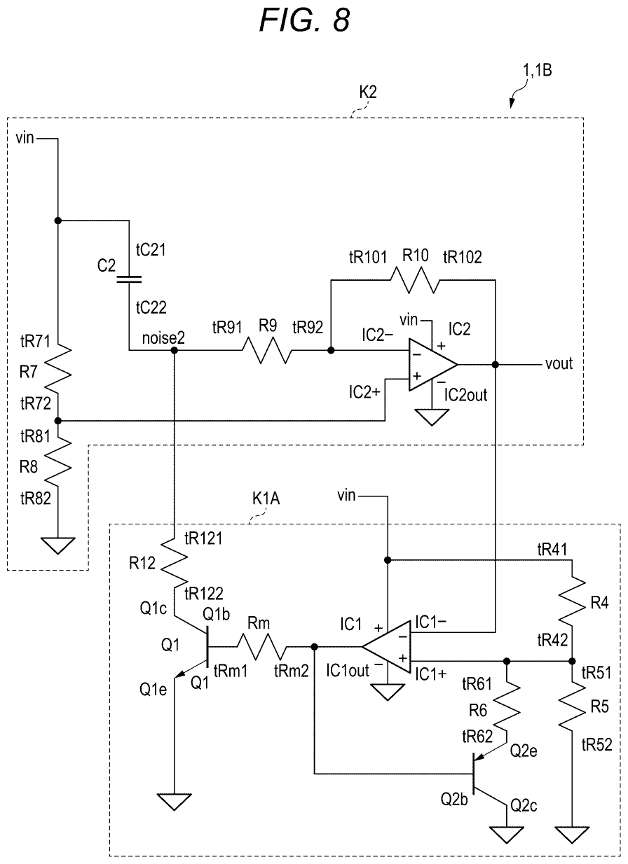

FIG. 8 is a diagram illustrating a case in which the voltage generation circuit 1 includes the bias power supply circuit K2 and an additional circuit KIA. In FIG. 8, the same components as those of the voltage generation circuit 1 illustrated in other drawings are denoted by the same reference numerals, and the description thereof will be omitted or simplified. The voltage generation circuit 1 including the bias power supply circuit K2 is also referred to as a voltage generation circuit 1B.

The bias power supply circuit K2 includes a resistor R7, a resistor R8, a capacitor C2, a resistor R9, a resistor R10, and the operational amplifier IC2. The resistor R7 includes a terminal tR71 and a terminal tR72. The resistor R8 includes a terminal tR81 and a terminal tR82. The capacitor C2 includes a terminal tC21 and a terminal tC22. The resistor R9 includes a terminal tR91 and a terminal tR92. The resistor R10 includes a terminal tR101 and a terminal tR102. The operational amplifier IC2 includes the inverting input terminal IC2−, the non-inverting input terminal IC2+, and the output terminal IC2out.

The terminal tR71, the terminal tC21, and the voltage input terminal Vin are electrically connected. The terminal tR72, the terminal tR81, and the non-inverting input terminal IC2+ are electrically connected. The terminal tR82 is electrically connected to a ground potential. The terminal tC22 and the terminal tR91 are electrically connected. A connection point between the terminal tC22 and the terminal tR91 is a point noise2. The terminal tR92, the terminal tR101, and the inverting input terminal IC2− are electrically connected. The terminal tR102, the output terminal IC2out, the voltage output terminal Vout, and the inverting input terminal IC1− are electrically connected.

The additional circuit KIA in FIG. 8 includes a resistor R12 and a resistor Rm in addition to the components of the additional circuit K1. The resistor R12 includes a terminal tR121 and a terminal tR122. The resistor Rm includes a terminal tRm1 and a terminal tRm2. The terminal tR 121, the terminal tR91, the terminal tC22, and the point noise2 are electrically connected. The terminal tR122 and the collector terminal Q1c are electrically connected. The terminal tRm1 and the base terminal Q1b are electrically connected. The terminal tRm2, the output terminal IC1out, and the base terminal Q2b are electrically connected.

FIG. 8 illustrates a case in which the transistor Q1 and the transistor Q2 are each a bipolar transistor. In this case, the resistor Rm for limiting a current is provided between the base terminal Q1b of the transistor Q1 and the output terminal IC1out of the operational amplifier IC1. The transistor Q1 and the transistor Q2 may be replaced with FET transistors. In this case, the resistor Rm illustrated in FIG. 8 may not be provided.

In FIG. 8, the resistance value of the resistor R4 is, for example, 4.7 (kΩ). The resistance value of the resistor R5 is, for example, 4.7 (kΩ). The resistance value of the resistor R6 is, for example, 4.7 (kΩ). A resistance value of the resistor R7 is, for example, 10 (kΩ). A resistance value of the resistor R8 is, for example, 10 (kΩ). A resistance value of the resistor R9 is, for example, 4.7 (kΩ). A resistance value of the resistor R10 is, for example, 4.7 (kΩ). A resistance value of the resistor Rm is, for example, 10 (kΩ). A resistance value of the resistor R12 is, for example, 200 (Ω). The capacitance value of the capacitor C1 is, for example, 220 (μF). The specific resistance values and the capacitance value of these elements are examples. When the same elements are illustrated in other drawings, resistance values and a capacitance value of the same elements may be set to the same values as or different values from these resistance values and the capacitance value within a range intended in the embodiment.

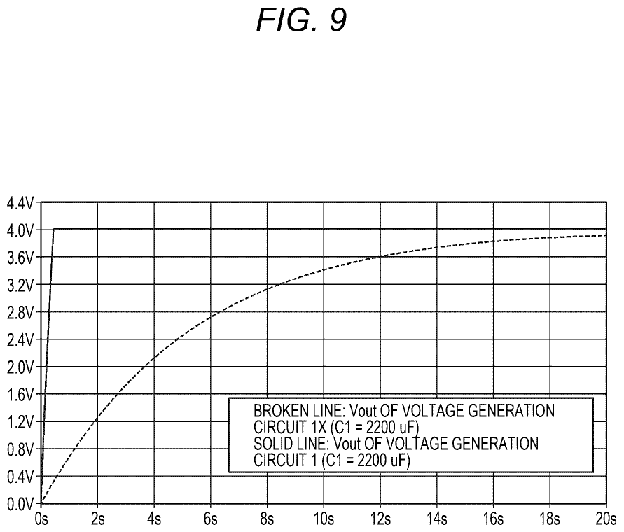

Effects of the present embodiment will be described with reference to FIG. 9. FIG. 9 is a diagram illustrating a change in the voltage at the point A of the voltage generation circuit 1X in a case in which the capacitor C20 has a capacitance value of 2200 μF and a change in the voltage at the point A of the voltage generation circuit 1 in a case in which the capacitor C1 has a capacitance value of 2200 μF.

As illustrated in FIG. 9, in the voltage generation circuit 1X, it takes, for example, 20 seconds or more for the voltage to stabilize. On the other hand, FIG. 9 illustrates that the output voltage is quickly stabilized in the voltage generation circuit 1.

Next, methods of designing constants of respective circuit elements of the voltage generation circuit 1 will be described.

### 1. Resistor R1, Resistor R2, and Capacitor C1

First, the constants of the resistor R1, the resistor R2, and the capacitor C1 will be described. Let Vin (V) be the input voltage input to the voltage input terminal Vin, Vo (V) be the output voltage output from the voltage output terminal Vout, and fc (Hz) be a cutoff frequency of a low-pass filter including the resistor R1, the resistor R2, and the capacitor C1, and the following relational formula is established. Hereinafter, names of the resistors are also used as resistance values in the formula, and a name of the capacitor is also used as a capacitance value of the capacitor in the formula.

$$[ Math . 1 ]$$

$$Vo = \frac{R 2}{R 1 + R 2} Vin ( V )$$

$$fc = \frac{1}{2 π \cdot C 1 \cdot R 1} ( Hz )$$

When the cutoff frequency fc is set to a lower frequency, a noise reduction effect implemented by the voltage generation circuit 1 is great. That is, as the values of the resistor R1 and the capacitor C1 increase, the noise reduction effect becomes greater, but the time required for the output voltage Vout to stabilize increases. In addition, when the resistance value is large, the voltage generation circuit 1 is easily affected by an external radiation noise, and when the capacitance value of the capacitor C1 is large, a component size increases. Therefore, it is preferable that the resistance value of the resistor R1 and the resistance value of the resistor R2 are set to 330Ω to 10 kΩ, and the capacitance value of the capacitor C1 is set to 100 uF to 2200 uF.

### 2. Transistor Q1 and Resistor R3

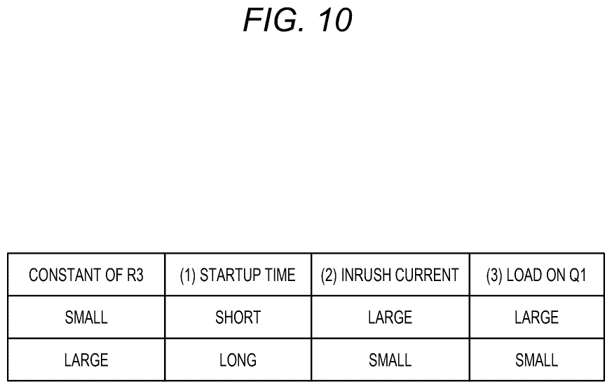

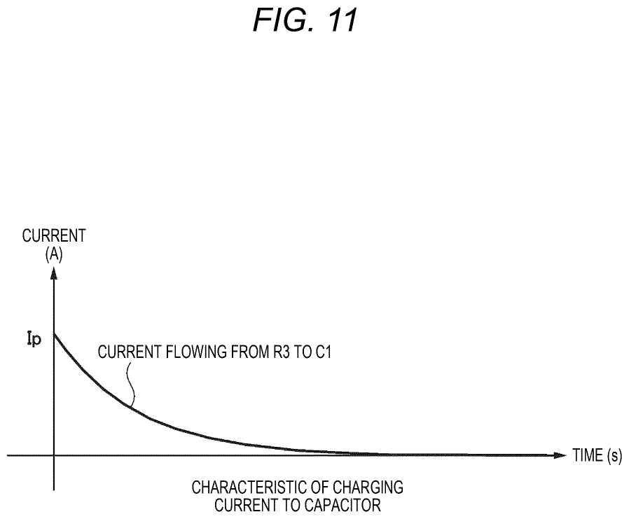

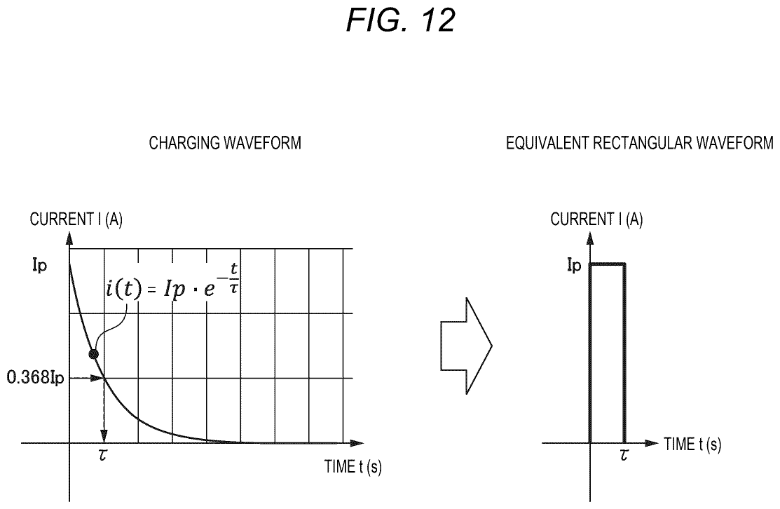

Next, the constants of the transistor Q1 and the resistor R3 will be described. FIG. 10 is a diagram comparing information regarding the resistor R3. FIG. 10 illustrates comparisons of times required for the output voltage of the voltage generation circuit 1 to stabilize, inrush currents flowing through the capacitor C1 when the transistor Q1 is turned on, and loads on the transistor Q1, according to the magnitude of the constant of the resistor R3. FIG. 11 is a diagram illustrating a characteristic of a charging current from the resistor R3 to the capacitor C1. FIG. 12 is a diagram illustrating a charging waveform and an equivalent rectangular waveform of the charging current of the capacitor C1.

As illustrated in FIG. 10, in the voltage generation circuit 1, when the inrush current flowing into the capacitor C1 at a moment when the transistor Q1 is turned on is increased, a rise of the output voltage Vout is accelerated, that is, a startup time can be shortened. The inrush current is represented by a peak value Ip in FIG. 11. On the other hand, when the inrush current increases, a load applied to the transistor Q1 and the resistor R3 increases. The load includes, for example, a thermal load. As illustrated in FIG. 11, the charging current for the capacitor C1 takes a maximum value as the inrush current at the moment when the transistor Q1 is turned on, and becomes the peak value Ip. For example, the peak value Ip is calculated as follows.

$$\begin{matrix}[ Math . 2 ] & \\ Ip = \frac{Vin}{R 3} ( A ) & Formula ( 1 )\end{matrix}$$

That is, it is necessary to determine the constant of the resistor R3 in consideration of the resistance of the resistor R1, the transistor Q1, the capacitor C1, and the like. First, when an electric charge is supplied from the resistor R3 to the capacitor C1, a current waveform as illustrated in FIG. 11 is obtained. This current waveform is a waveform of the charging current and is called the charging waveform. As illustrated in FIG. 12, when the charging current is a predetermined allowable current, the charging waveform can be replaced with the equivalent rectangular waveform determined by the peak value Ip and a time constant t and used to calculate an allowable current and a power. The time constant t indicates a duration of charging. The time constant τ is calculated as follows, for example.

$$τ = C 1 \cdot R 3 ( s ) \qquad Formula ( 2 )$$

Next, in consideration of an allowable current of the transistor Q1, the peak value Ip is determined, and the constant of the resistor R3 is determined.

When the transistor Q1 is, for example, a transistor having a size of about 2 mm square, an allowable current for one pulse of 100 msec or less is 80 mA when the input voltage Vin is, for example, about 8 V. In addition, in a case in which a usage environment is a high temperature environment or the like, when a derating of 50% is taken into consideration, for example, the allowable current for one pulse of 100 msec or less is 40 mA. From the above, the constant of the resistor R3 at which the peak value Ip is 40 mA is calculated to be 200Ω based on Formula (1).

Next, a component size is determined based on a power consumed by the resistor R3.

A calculation for obtaining a power P based on the equivalent rectangular waveform in FIG. 12 can be expressed by, for example, Formula (3). Here, when Formula (3) is modified based on Formula (1) and Formula (2), Formula (4) is obtained. Therefore, the power P can be calculated based on the input voltage Vin and the capacitance value of the capacitor C1 regardless of the value of the resistor R3.

$$\begin{matrix}[ Math . 3 ] & \\ P = \frac{1}{2} {Ip}^{2} \cdot τ \cdot R 3 ( W ) & Formula ( 3 )\end{matrix}$$

$$P = \frac{1}{2} {Vin}^{2} \cdot C 2 ( W ) \qquad Formula ( 4 )$$

Therefore, when the input voltage Vin is 8 V and the capacitance value of the capacitor C2 is 220 uF, the power P consumed by the resistor R3 is 0.00704 W according to Formula (4). When the resistor R3 is a general thick-film chip resistor, a rated power of the resistor R3 having 1005 size is 0.1 W, and therefore, it can be determined that there is no problem.

### [Math. 4]

When a current i(t) flows through a 1Ω resistor, the current can be expressed, for example, by the following equation.

$$I = Ip \cdot τ ( A )$$

Also, when a current i(t) flows through a 1Ω resistor, the power P can be expressed, for example, by the following equation.

$$P = \frac{1}{2} {Ip}^{2} \cdot τ ( W )$$

When the allowable current is examined, another method may be considered in order to obtain the allowable current more accurately. In the above-described calculation, the calculation is performed using an equivalent rectangular waveform in a case in which the supply of the electric charge to the capacitor C1 is performed for an infinite time. In the voltage generation circuit 1, the supply of the electric charge to the capacitor C1 is stopped when a set output voltage Vout is reached, and therefore, it is preferable that the calculation is performed using the equivalent rectangular waveform in a finite time. When a time obtained by multiplying the time constant t by a ratio between the output voltage Vout and the input voltage Vin is considered as the duration of charging, the peak value Ip and the duration can be used for more accurate current and power calculations. In the above-described example, the output voltage Vout is 4 V, and the input voltage Vin is 8 V, and therefore, Vo/Vin is 0.5, and a current value may be considered to be half. That is, although the resistance value of the resistor R3 is set to 200Ω for a target current of 40 mA, the resistance value of the resistor R3 may be set to 100Ω for a target current of 80 mA. In addition, the power may be calculated based on Formula (5), and a calculation more suitable for an actual situation is possible.

$$\begin{matrix}[ Math . 5 ] & \\ P = \frac{1}{2} {Vin}^{2} \cdot C 2 \cdot ( 1 - {( \frac{Vout}{Vin} )}^{2} ) ( W ) & Formula ( 5 )\end{matrix}$$

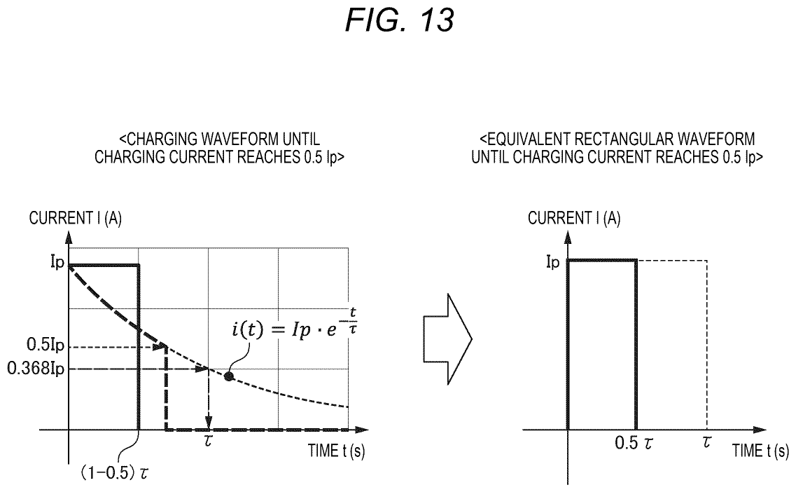

An example of calculating a current and a power using an equivalent rectangular waveform in a finite time will be described with reference to FIG. 13. FIG. 13 is a diagram illustrating a charging waveform and an equivalent rectangular waveform of the capacitor C1. In an example illustrated in FIG. 13, in the voltage generation circuit 1, the supply of the electric charge to the capacitor C1 is stopped when the current reaches 0.5 Ip. Therefore, the current thereafter becomes 0.

### [Math. 6]

When a current i (t) up to 0.5 Ip flows through a 1 Ω resistor, the current can be expressed, for example, by the following equation.

$$I = Ip \cdot τ \cdot ( 1 - 0.5 ) ( A )$$

When a current i (t) up to 0.5 Ip flows through a 1 Ω resistor, the power P can be expressed, for example, by the following equation.

$$P = \frac{1}{2} {Ip}^{2} \cdot τ \cdot ( 1 - {( 0.5 )}^{2} ) ( W )$$

Next, a relation between the output voltage/input voltage and a reduction coefficient K will be described.

The reduction coefficient K is (1−(Vout/Vin)²) described in Formula (5). In other words, the reduction coefficient K takes a value of 0 or more and 1 or less. That is, as the reduction coefficient K decreases, a degree of reduction increases, and the power P decreases.

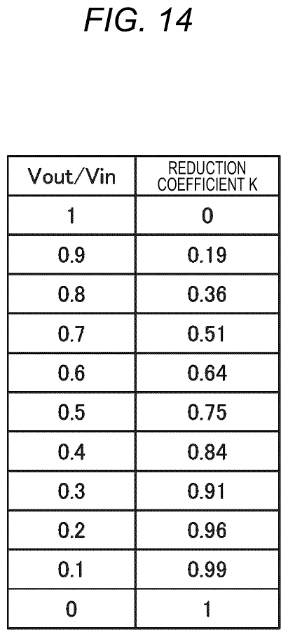

FIG. 14 is a table illustrating the relation between the output voltage/input voltage and the reduction coefficient K.

As can be seen from the relation between the output voltage/input voltage and the reduction coefficient K in FIG. 14, when the output voltage Vout is a value close to the input voltage Vin, the degree of reduction increases. For example, even when the output voltage Vout is a half voltage of the input voltage Vin, it can be understood that the power P used as power consumption can be reduced by 75%.

### 3. Resistor R4, Resistor R5, and Resistor R6

Next, the resistor R4, the resistor R5, and the resistor R6 will be described.

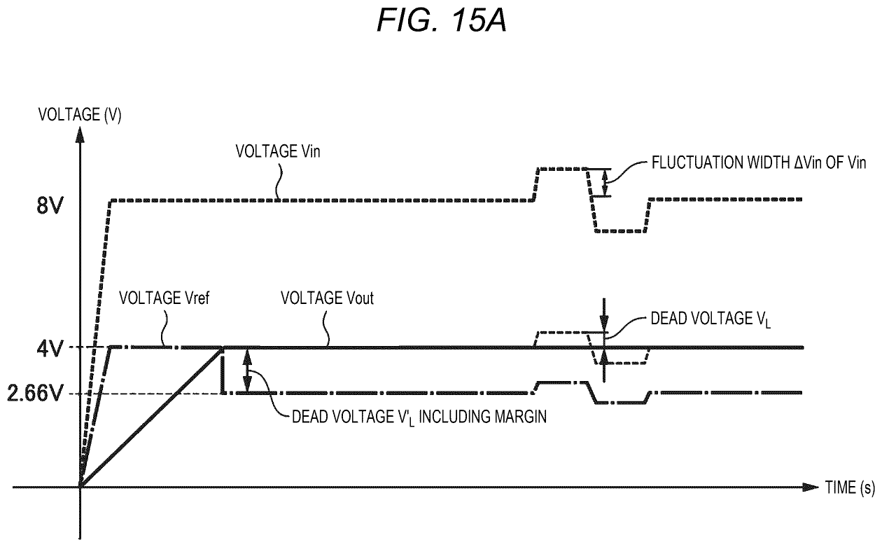

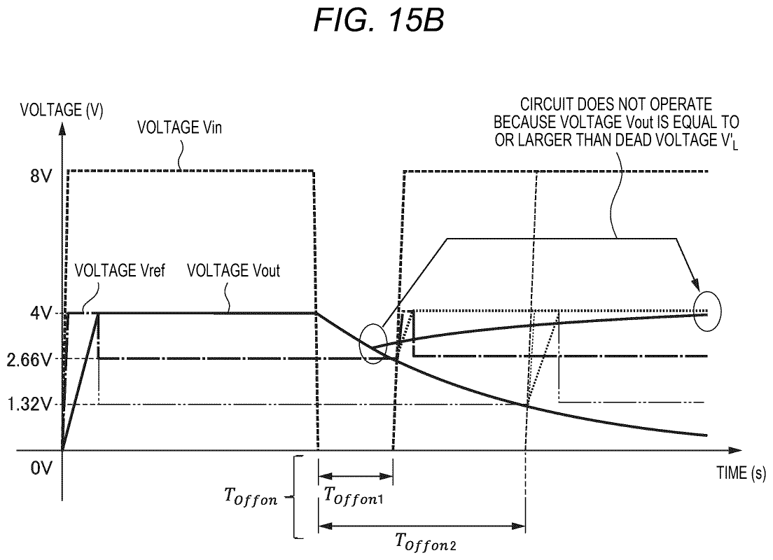

FIG. 15A is a diagram illustrating a dead voltage. FIG. 15B is a diagram illustrating a time Toffon for turning on a power supply again.

The resistor R4 and the resistor R5 generate a reference voltage Vref for stopping the supply of the electric charge to the capacitor C1 when the output voltage Vout reaches a predetermined voltage after the power supply of the voltage generation circuit 1 is turned on. A voltage obtained by dividing a power supply voltage, that is, the input voltage Vin by the resistance value of the resistor R4 and the resistance value of the resistor R5 is generated as the reference voltage Vref. An example of a relational formula of the reference voltage Vref is illustrated in Formula (6).

$$\begin{matrix}[ Math . 7 ] & \\ Vref = \frac{R 5}{R 4 + R 5} \cdot Vin ( V ) & Formula ( 6 )\end{matrix}$$

Considering that a current always flows through the resistor R4 and the resistor R5, it is preferable that the resistance value of the resistor R4 and the resistance value of the resistor R5 are set in a range of 1 kΩ to 33 kΩ. In addition, the resistor R6 is a resistor that determines a dead voltage V_{L} for preventing the supply of the electric charge to the capacitor C1 from being started again due to a temporary fluctuation of the input voltage Vin after the supply of the current to the capacitor C1 is stopped. The temporary fluctuation of the input voltage Vin is illustrated in FIG. 15A. It is preferable that the dead voltage V_{L} is calculated based on an assumed fluctuation width ΔVin of the input voltage Vin and the time Toffon for turning on the power supply again.

As described above, the fluctuation of the input voltage Vin occurs due to the external noise or the like. In addition, it is assumed that the power supply is turned on again in a case in which the application of the input voltage Vin of the voltage generation circuit 1 is temporarily stopped and input, that is, applied again. A relation between the dead voltage V_{L} and the fluctuation width Δvin can be expressed by, for example, Formula (7).

$$\begin{matrix}[ Math . 8 ] & \\ {V}_{L} = \frac{R 5}{R 4 + R 5} \cdot Δ Vin ( V ) & Formula ( 7 )\end{matrix}$$

When a dead voltage V_{L}′ obtained by adding a margin to the calculated dead voltage V_{L} is determined, the resistance value of the resistor R6 can be expressed by, for example, the following Formula (8).

$$\begin{matrix}[ Math . 9 ] & \\ R 6 = \frac{\frac{1}{Vref} - \frac{1}{Vin}}{\frac{1}{Vref - {V}_{L}^{′}} - \frac{1}{Vref}} \cdot R 9 ( Ω ) & Formula ( 8 )\end{matrix}$$

Here, it is necessary to consider the time Toffon for turning on the power supply again based on the calculated dead voltage V_{L}′. A plurality of examples of the time Toffon are illustrated in FIG. 15B. The time Toffon is preferably small.

In the voltage generation circuit 1, when the dead voltage V_{L}′ is increased, a malfunction caused by a power supply fluctuation, that is, the fluctuation of the input voltage Vin can be prevented. On the other hand, in the voltage generation circuit 1, after the power supply is turned off, the power supply cannot be turned on again until the output voltage Vout decreases by the dead voltage V_{L}′. An indication for turning on the power supply again can be expressed by, for example, the following Formula (9).

$$\begin{matrix}[ Math . 10 ] & \\ {T}_{Offon} = R 2 \cdot C 1 \cdot ln \frac{Vref}{Vref - {V}_{L}^{′}} ( s ) & Formula ( 9 )\end{matrix}$$

For example, when the capacitance value of the capacitor C1 is 220 uF, the constant of the resistor R2 is 4.7 kΩ, and the reference voltage Vref is 4 V, the time Toffon in a case in which the dead voltage V_{L}′ is 1.34 V, in other words, a time Toffon1 is 0.42 s. With respect to this, the time Toffon in a case in which the dead voltage V_{L}′ is 2.68 V, which is twice 1.34 V, in other words, a time Toffon2 is 1.146 s, which is 2.73 times the time Toffon1=0.42 s. That is, it can be understood that the time Toffon increases when the dead voltage V_{L}′ is increased.

### 4. Transistor Q2

In the voltage generation circuit 1, the transistor Q2 is operated based on an output signal from the operational amplifier IC1 to cause a current to flow through the resistor R6, thereby changing the reference voltage Vref. At this time, since the current flowing through the resistor R6 becomes a collector current of the transistor Q2, it is preferable to select the transistor Q2 based on the current flowing through the resistor R6. Since the PNP bipolar transistor is used in a switching region, the transistor Q2 is assumed to have a small on resistance, and the current is calculated. The current flowing through the resistor R6 when the transistor Q2 is turned on is expressed by, for example, Formula (10).

$$\begin{matrix}[ Math . 11 ] & \\ {I}_{R 6} = \frac{Vref - {V}_{L}}{R 6} ( A ) & Formula ( 10 )\end{matrix}$$

As an example, when the reference voltage Vref is 4 V, the dead voltage V_{L} is 1.34 V, and the resistance value of the resistor R6 is 4.7 kΩ, a current I_{R6} flowing through the resistor R6 is calculated as 0.566 mA. Therefore, it is preferable to select the transistor Q2 based on a rated value of the collector current of the transistor Q2.

### 5. Operational Amplifier IC1

The operational amplifier IC1 compares the output voltage Vout, that is, the voltage at the point A with the reference voltage Vref, that is, the voltage at the point B. The operational amplifier IC1 performs a positive output, that is, outputs a High voltage when the output voltage Vout is smaller, and performs a 0 V output, that is, outputs a Low voltage when the output voltage Vout is larger. The operational amplifier IC1 supplies a base current to the transistor Q1 and controls the voltage such that the transistor Q1 can be used in a saturation region when performing the positive output. In this case, the operational amplifier IC1 capable of supplying a current of 1/hfe with respect to the peak value Ip of the charging waveform used when the resistor R3 is designed for the collector current flowing through the transistor Q1 is selected. In a case of the transistor Q1 of about 2 mm square, since hfe is 300, a current of Ip/hfe is about 133 uA. Here, hfe is a current amplification factor at the time when an emitter is grounded.

Further, the operational amplifier IC1 draws a base current of the transistor Q2 when performing 0 V output. Similarly, for the transistor Q2, the operational amplifier IC1 that can draw the current of 1/hfe with respect to the collector current of the transistor Q2 is selected. In a case of the transistor Q2 of about 2 mm square, since hfe is 300, when the current flowing through the resistor R6 is I_{R6}, the current of I_{R6}/hfe is about 1.9 uA. As the operational amplifier IC1, for example, a general voltage feedback operational amplifier may be selected.

On the other hand, when the input voltage Vin is rapidly removed, that is, is not applied, in the inverting input terminal IC1−, a potential of the inverting input terminal IC1− of the operational amplifier IC1 becomes larger than that of the power supply terminal of the operational amplifier IC1 due to the electric charge remaining in the capacitor C1. Therefore, it is necessary to select the operational amplifier IC1 in consideration of an absolute rating. When the absolute rating of the operational amplifier IC1 is exceeded, it may be considered to either prevent the input voltage Vin from being rapidly removed or to insert a Schottky barrier diode. Details of the Schottky barrier diode will be described later.

### <Modification of Voltage Generation Circuit>

Next, an arrange circuit serving as a modification of the voltage generation circuit 1 will be described. The arrange circuit may be applied to the voltage generation circuit 1B. First, a positive voltage output from a positive power supply will be described.

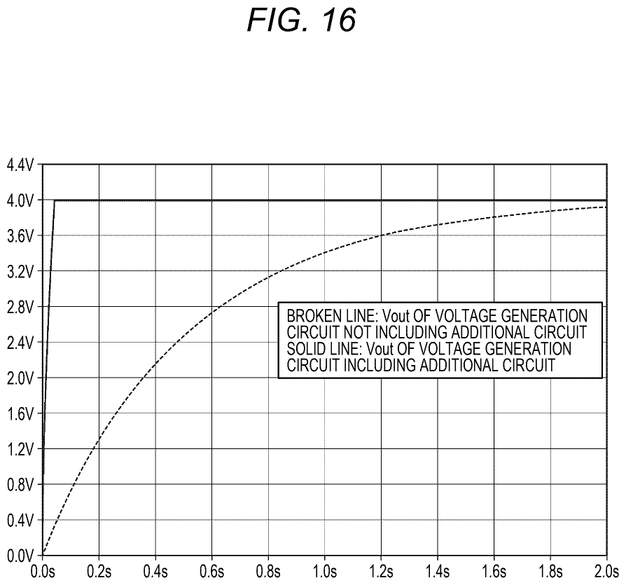

FIG. 16 is a diagram illustrating the output voltage Vout in a case in which the positive voltage is output from the positive power supply in the voltage generation circuit 1. The voltage generation circuit 1 is, for example, the voltage generation circuit 1 in FIG. 3A. In FIG. 16, a horizontal axis represents time, and a vertical axis represents voltage value.

In FIG. 16, a case in which the additional circuit K1 is provided is compared with a case in which the additional circuit K1 is not provided. Referring to FIG. 16, the output voltage Vout can be quickly stabilized in the voltage generation circuit 1 including the additional circuit K1 as compared with a voltage generation circuit not including the additional circuit K1.

In the voltage generation circuit 1, the operational amplifier IC1 may be changed to a comparator. The operational amplifier IC1 amplifies a difference between an input to the non-inverting input terminal IC1+ and an input to the inverting input terminal IC1−. If a voltage input to the non-inverting input terminal IC1+ and a voltage input to the inverting input terminal IC1− are the same, the operational amplifier IC1 outputs a voltage of OV. With respect to this, the comparator compares the voltage input to the non-inverting input terminal IC1+ with the voltage input to the inverting input terminal IC1−, and outputs a High voltage or a Low voltage. Even when the comparator is used instead of the operational amplifier IC1 in the voltage generation circuit 1, a result illustrated in FIG. 16 is obtained.

Next, a negative voltage output from a negative power supply will be described.

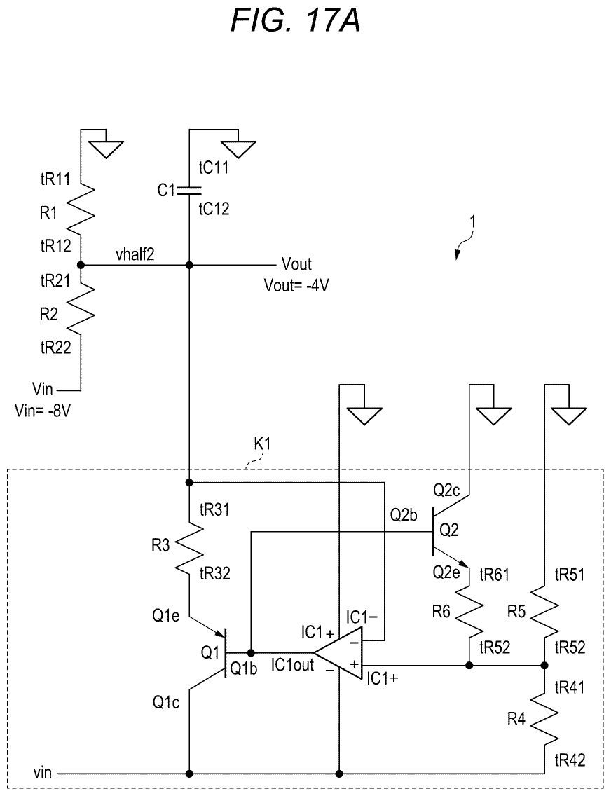

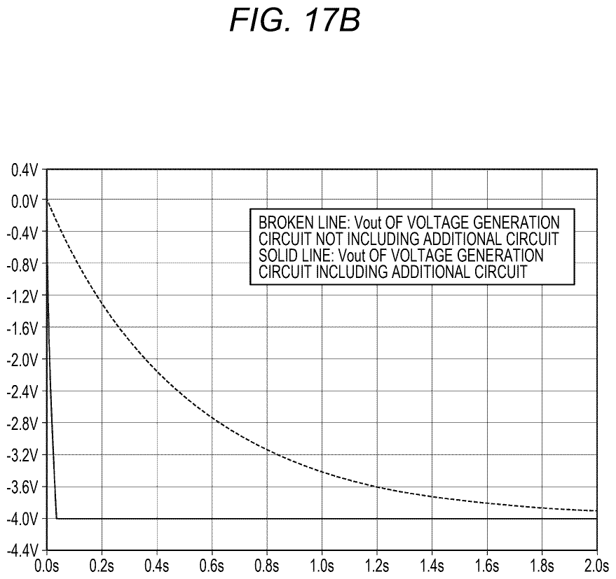

A case in which a negative voltage is output from the negative power supply in the voltage generation circuit 1 will be described with reference to FIGS. 17A and 17B. FIG. 17A is a diagram illustrating a configuration of the voltage generation circuit 1. In FIG. 17A, the same components as those of the voltage generation circuit 1 illustrated in other drawings are denoted by the same reference numerals, and the description thereof will be omitted or simplified. FIG. 17B is a diagram illustrating the output voltage Vout. In FIG. 17B, a horizontal axis represents time, and a vertical axis represents voltage value.

In FIG. 17A, the input voltage Vin is, for example, −8 V, and the output voltage Vout is, for example, −4 V. Even in this case, the output voltage Vout can be quickly stabilized in the voltage generation circuit 1 including the additional circuit K1 as compared with the voltage generation circuit not including the additional circuit K1.

Next, a first example of a positive voltage output in a dual power supply circuit will be described.

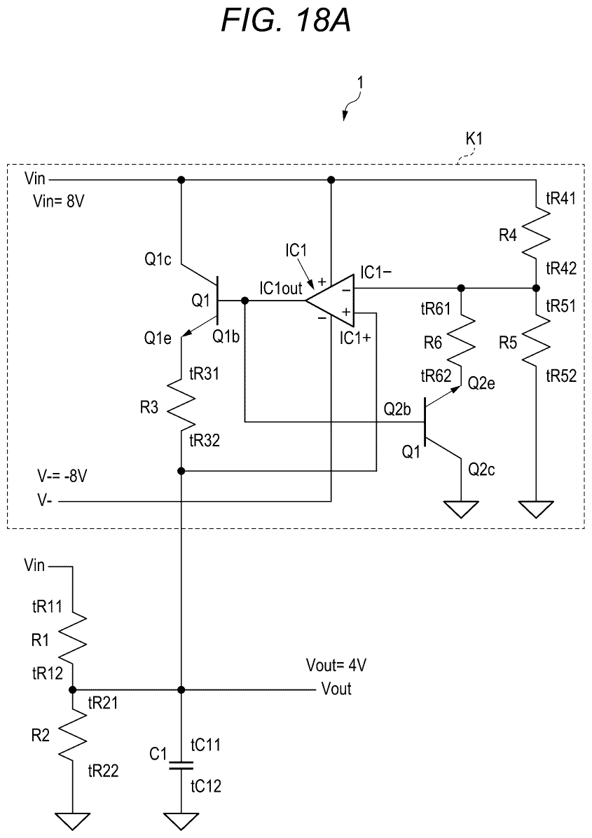

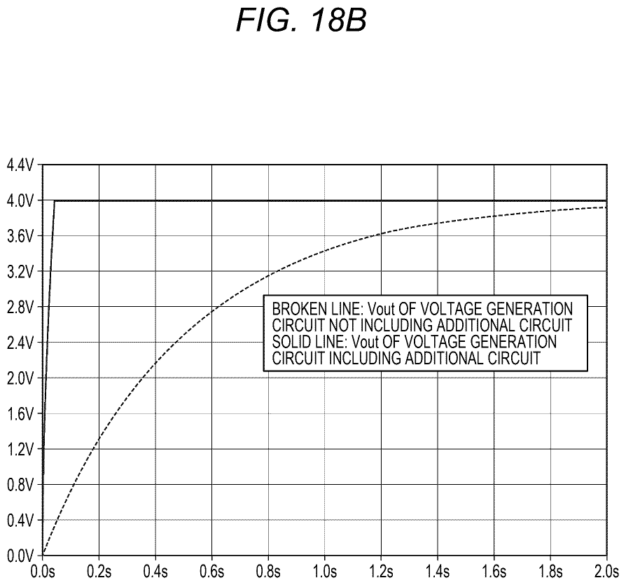

FIGS. 18A and 18B are each a diagram illustrating a case in which the voltage generation circuit 1 serving as the dual power supply circuit outputs the positive voltage. FIG. 18A is a diagram illustrating a configuration of the voltage generation circuit 1. In FIG. 18A, the same components as those of the voltage generation circuit 1 illustrated in other drawings are denoted by the same reference numerals, and the description thereof will be omitted or simplified. FIG. 18B is a diagram illustrating the output voltage Vout. In FIG. 18B, a horizontal axis represents time, and a vertical axis represents voltage value.

In the voltage generation circuit 1, a voltage of, for example, 8V is input as the input voltage Vin of the positive voltage, a voltage of, for example, −8V is input as an input voltage V− of the negative voltage, and a voltage of, for example, 4V is output as the output voltage Vout. Even in this case, the output voltage Vout can be quickly stabilized in the voltage generation circuit 1 as compared with the voltage generation circuit not including the additional circuit K1.

Next, a second example of the positive voltage output in the dual power supply circuit will be described.

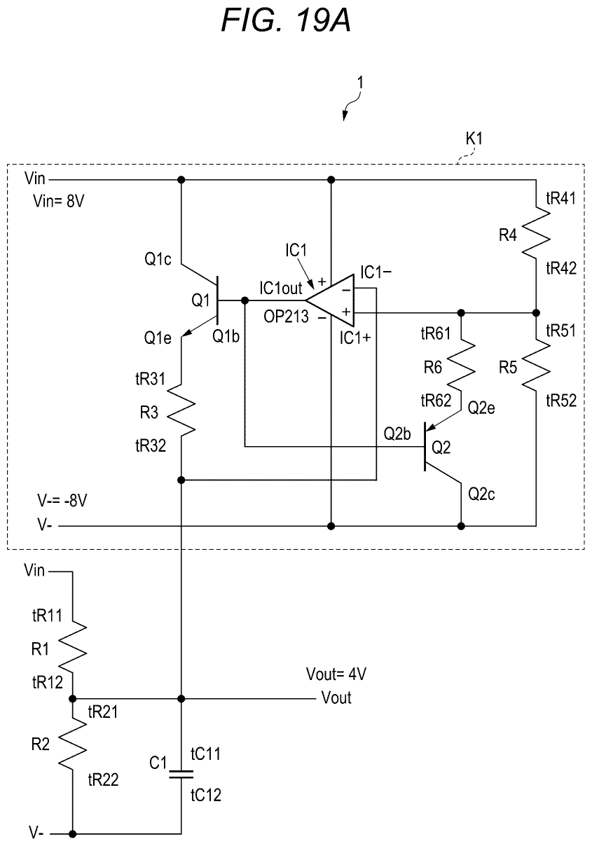

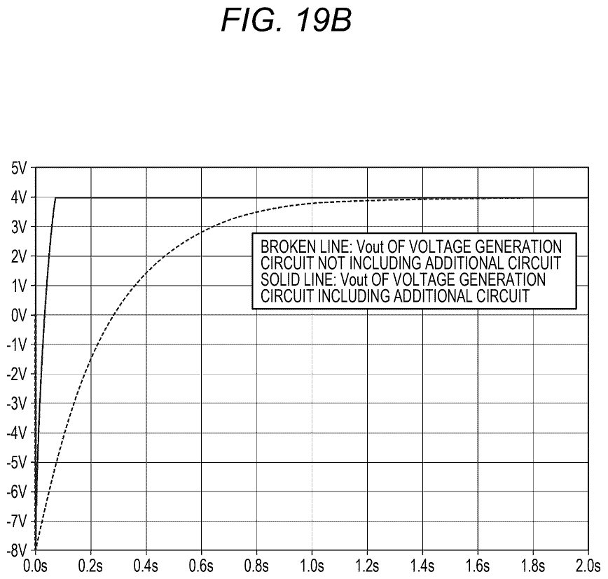

Another case in which the voltage generation circuit 1 serving as the dual power supply circuit outputs the positive voltage will be described with reference to FIGS. 19A and 19B. FIG. 19A is a diagram illustrating a configuration of the voltage generation circuit 1. In FIG. 19A, the same components as those of the voltage generation circuit 1 illustrated in other drawings are denoted by the same reference numerals, and the description thereof will be omitted or simplified. FIG. 19B is a diagram illustrating the output voltage Vout. In FIG. 19B, a horizontal axis represents time, and a vertical axis represents voltage value.

In the voltage generation circuit 1, a voltage of, for example, 8V is input as the input voltage Vin of the positive voltage, a voltage of, for example, −8V is input as the input voltage V− of the negative voltage, and a voltage of, for example, 4V is output as the output voltage Vout. The collector terminal Q2c, the terminal tR52, the terminal tR22, and the terminal tC12 are electrically connected to the negative voltage V−. In an example illustrated in FIG. 19A, a ratio of the resistance value of the resistor R1 to the resistance value of the resistor R2 and a ratio of the resistance value of the resistor R4 to the resistance value of the resistor R5 are adjusted such that the output voltage Vout reaches 4 V. For example, (resistance value of resistor R1):(resistance value of resistor R2)=(resistance value of resistor R4):(resistance value of resistor R5)=1.567 (kΩ): 4.7 (kΩ). Even in this case, the output voltage Vout can be quickly stabilized in the voltage generation circuit 1 as compared with the voltage generation circuit not including the additional circuit K1.

Next, a negative voltage output in a negative power supply circuit will be described.

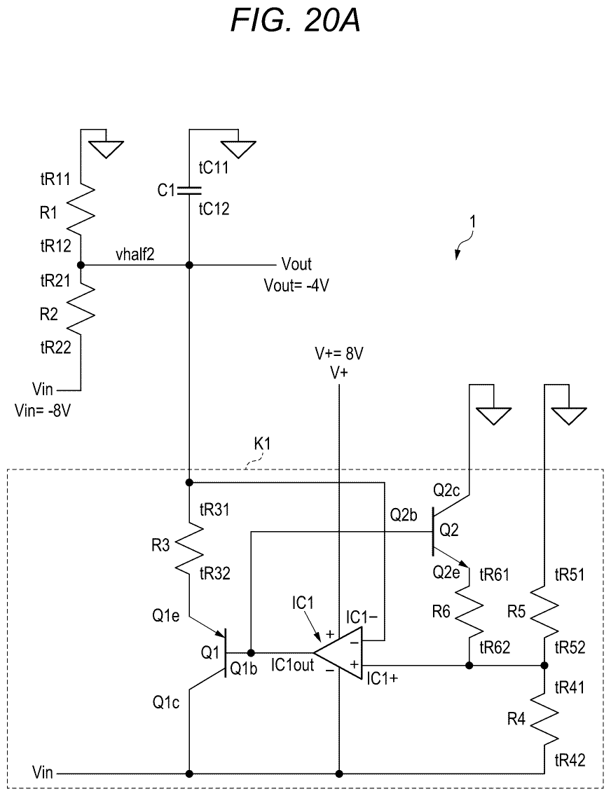

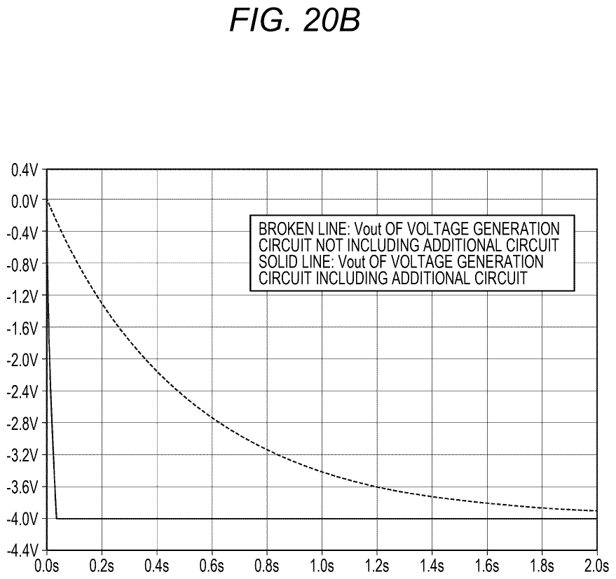

A case in which the voltage generation circuit 1 serving as the negative power supply circuit outputs a negative voltage will be described with reference to FIGS. 20A and 20B. FIG. 20A is a diagram illustrating a configuration of the voltage generation circuit 1. In FIG. 20A, the same components as those of the voltage generation circuit 1 illustrated in other drawings are denoted by the same reference numerals, and the description thereof will be omitted or simplified. FIG. 20B is a diagram illustrating the output voltage Vout. In FIG. 20B, a horizontal axis represents time, and a vertical axis represents voltage value.

In the voltage generation circuit 1, a voltage of, for example, −8V is input as the input voltage Vin of the negative voltage, a voltage of, for example, 8V is input as an input voltage V+ of the positive voltage, and a voltage of, for example, −4V is output as the output voltage Vout. The input voltage V+ is input as a positive power supply voltage of the operational amplifier IC1. Even in this case, the output voltage Vout can be quickly stabilized in the voltage generation circuit 1 as compared with the voltage generation circuit not including the additional circuit K1.

Next, a negative voltage output in the dual power supply circuit will be described.

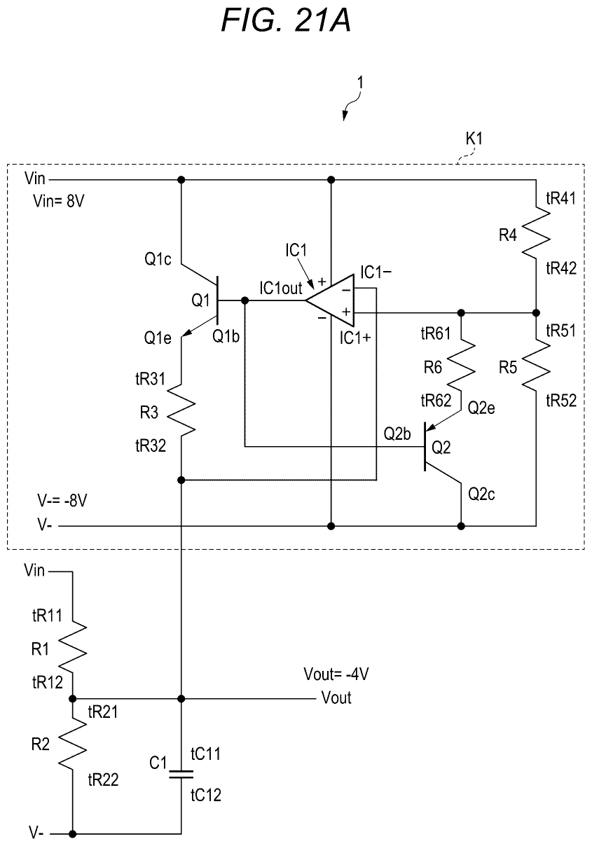

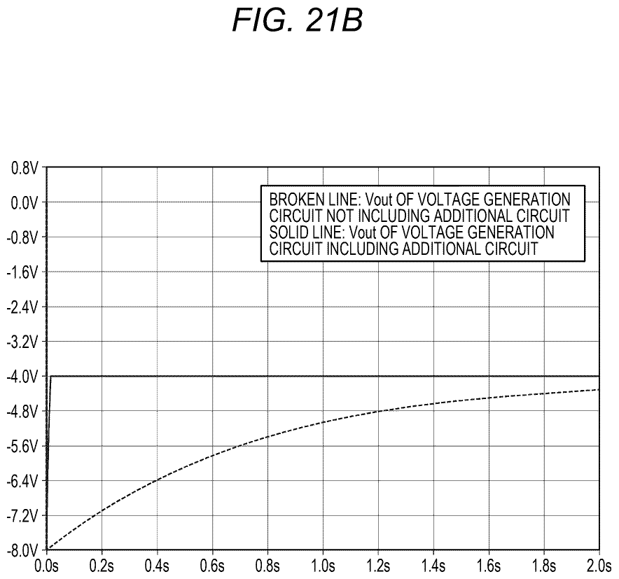

A case in which the voltage generation circuit 1 serving as the dual power supply circuit outputs a negative voltage will be described with reference to FIGS. 21A and 21B. FIG. 21A is a diagram illustrating a configuration of the voltage generation circuit 1. In FIG. 21A, the same components as those of the voltage generation circuit 1 illustrated in other drawings are denoted by the same reference numerals, and the description thereof will be omitted or simplified. FIG. 21B is a diagram illustrating the output voltage Vout. In FIG. 21B, a horizontal axis represents time, and a vertical axis represents voltage value.

In the voltage generation circuit 1, a voltage of, for example, 8V is input as the input voltage Vin of the positive voltage, a voltage of, for example, −8V is input as the input voltage V− of the negative voltage, and a voltage of, for example, −4V is output as the output voltage Vout. The collector terminal Q2c, the terminal tR52, the terminal tR22, and the terminal tC12 are electrically connected to the negative voltage V−. In an example illustrated in FIG. 21A, the ratio of the resistance value of the resistor R1 to the resistance value of the resistor R2 and the ratio of the resistance value of the resistor R4 to the resistance value of the resistor R5 are adjusted such that the output voltage Vout reaches-4 V. For example, (resistance value of resistor R1):(resistance value of resistor R2)=(resistance value of resistor R4):(resistance value of resistor R5)=14.1 (kΩ): 4.7 (kΩ). Even in this case, the output voltage Vout can be quickly stabilized in the voltage generation circuit 1 as compared with the voltage generation circuit not including the additional circuit K1.

Next, a case in which safety at the time of failure of the voltage generation circuit 1 is further improved will be described.

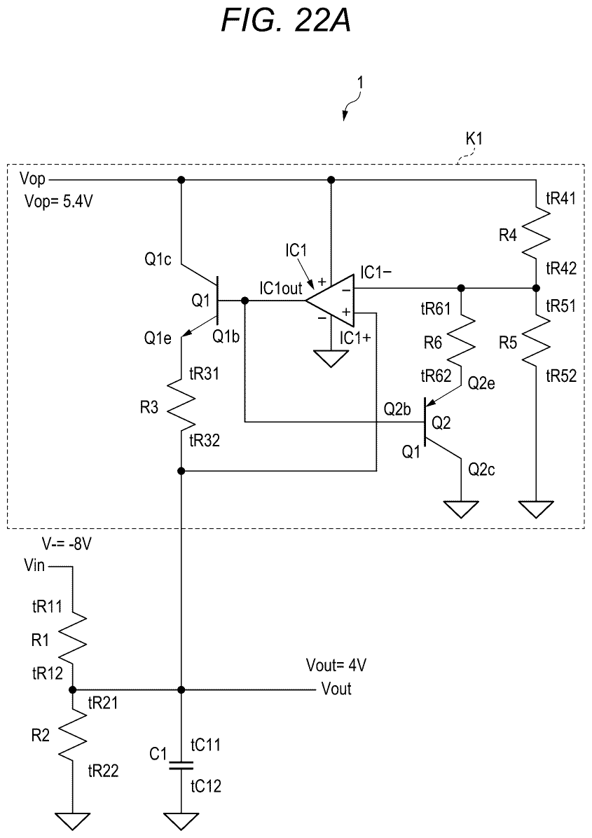

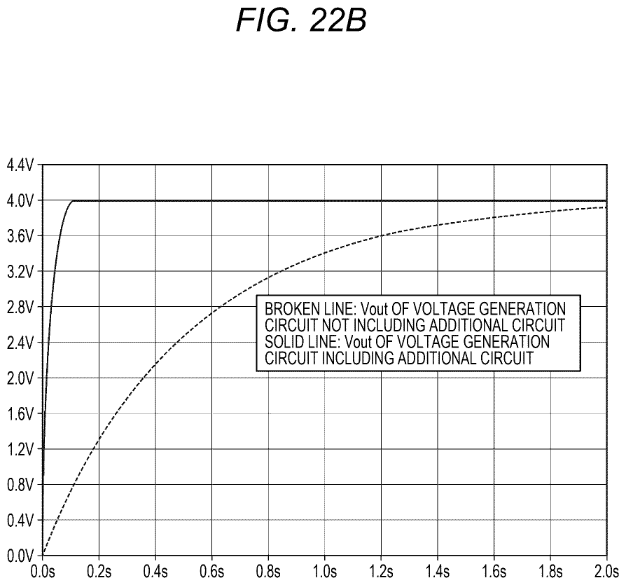

The case in which the safety at the time of failure is further improved in the voltage generation circuit 1 will be described with reference to FIGS. 22A and 22B. FIG. 22A is a diagram illustrating a configuration of the voltage generation circuit 1. In FIG. 22A, the same components as those of the voltage generation circuit 1 illustrated in other drawings are denoted by the same reference numerals, and the description thereof will be omitted or simplified. FIG. 22B is a diagram illustrating the output voltage Vout. In FIG. 22B, a horizontal axis represents time, and a vertical axis represents voltage value.

The voltage generation circuit 1 in FIG. 22A is similar to the voltage generation circuit 1 in FIG. 3A in that the input voltage Vin to the voltage divider circuit K0 is 8 V. An input voltage Vop to the additional circuit K1 is 5.4 V. In the voltage generation circuit 1, the output voltage Vout may be controlled using a minimum input voltage Vop of, for example, 5.4V. A minimum voltage of the input voltage Vop is, for example, a voltage obtained by adding the output voltage Vout, a maximum output voltage of the operational amplifier IC1, and a VBE voltage of the transistor Q1. When the voltage generation circuit 1 includes an FET instead of the bipolar transistor, a Vth voltage, which is a gate-source voltage, is used instead of the VBE voltage.

When the transistor Q1 fails and is short-circuited, the input voltage Vop is output as the output voltage Vout as it is. If the transistor Q1 is short-circuited when the input voltage Vin of 8 V is used as an input voltage to the additional circuit K1, the input voltage Vout of 8 Vis output as the output voltage Vout. Since the original output voltage Vout is 4 V, when a voltage significantly larger than 4 V is output, it may lead to a failure of a device that is an output destination. On the other hand, when the input voltage Vop is used as the input voltage to the additional circuit K1, the output voltage Vout is controlled to 5.4 V even when the transistor Q1 is short-circuited. Accordingly, the voltage generation circuit 1 can protect the device connected to the output voltage Vout even when the transistor Q1 fails and is short-circuited. Further, the output voltage Vout can be quickly stabilized also in the voltage generation circuit 1 in FIG. 22 as compared with the voltage generation circuit not including the additional circuit K1.

Next, a case in which the voltage generation circuit 1 is applied to a regulator output will be described.

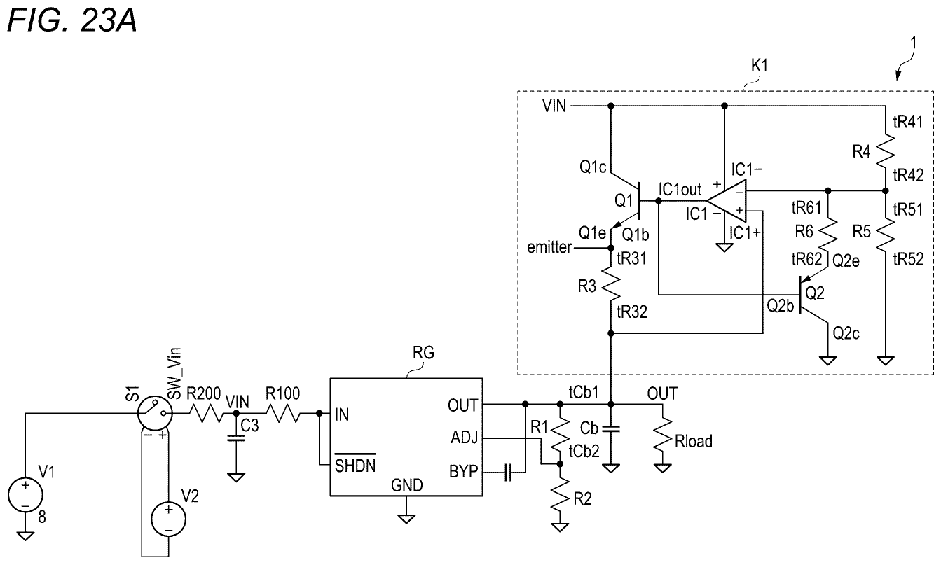

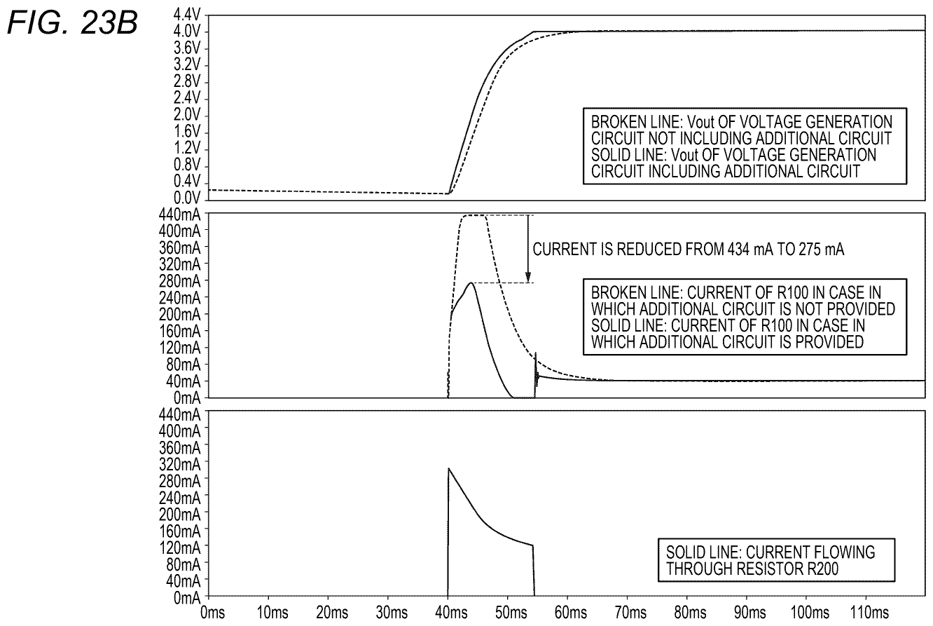

The case in which the voltage generation circuit 1 is applied to the regulator output will be described with reference to FIGS. 23A and 23B. FIG. 23A is a diagram illustrating configurations of the voltage generation circuit 1 and a peripheral circuit thereof. In FIG. 23A, the same components as those of the voltage generation circuit 1 illustrated in other drawings are denoted by the same reference numerals, and the description thereof will be omitted or simplified. FIG. 23B is a diagram illustrating the output voltage Vout, inrush currents to a regulator RG, and a bypass current passing through the additional circuit K1. In FIG. 23B, horizontal axes represent time, and vertical axes represent voltage value or current value.

The voltage generation circuit 1 in FIG. 23A is different from the above-described voltage generation circuit 1 in that a capacitor Cb is connected to a terminal of the resistor R1 on a side not connected to the resistor R2. An OUT terminal of the regulator RG is electrically connected to the voltage input terminal Vin of the voltage generation circuit 1. That is, an output voltage of the regulator RG serving as the regulator output becomes the input voltage Vin of the voltage generation circuit 1. An IN terminal of the regulator RG is electrically connected to a resistor R100. The other terminal of the resistor R100 is electrically connected to a voltage input terminal VIN. The voltage input terminal VIN is connected to a voltage input terminal VIN of the additional circuit K1. The resistor R100 is a resistor introduced for describing the inrush current described later, and the resistance value thereof may be significantly smaller than that of the resistor R1 or the like.

In FIG. 23B, in an upper graph, the output voltage Vout of the voltage generation circuit not including the additional circuit K1 and the output voltage Vout of the voltage generation circuit 1 in FIG. 23A are illustrated in time series. In the upper graph, a case of the voltage generation circuit not including the additional circuit K1 is indicated by a broken line, and a case of FIG. 23A is indicated by a solid line.

In FIG. 23B, in a middle graph, a current flowing through the resistor R100 when the voltage generation circuit does not include the additional circuit K1 and is applied to the regulator output and a current flowing through the resistor R100 when the voltage generation circuit 1 in FIG. 23A is applied to the regulator output are illustrated in time series. The current flowing through the resistor R100 corresponds to the inrush current to the regulator RG. In the middle graph, a case of the voltage generation circuit not including the additional circuit K1 is indicated by a broken line, and a case of the voltage generation circuit 1 in FIG. 23A is indicated by a solid line.

In FIG. 23B, in a lower graph, a current flowing through a resistor R200 of the voltage generation circuit 1 in FIG. 23A is illustrated. The current flowing through the resistor R200 corresponds to the bypass current passing through the additional circuit K1.

As illustrated in FIG. 23B, in the voltage generation circuit 1, the inrush current to the regulator RG can be reduced when the regulator RG is started up. Specifically, as illustrated in the middle graph in FIG. 23B, in the voltage generation circuit 1, the inrush current can be reduced from 434 mA to 275 mA, for example. This is because the current is bypassed from the voltage input terminal VIN to the voltage input terminal VIN of the additional circuit K1 because the voltage input terminal VIN is connected to the voltage input terminal VIN of the additional circuit K1. Further, as illustrated in the upper graph in FIG. 23B, the output voltage Vout can be quickly stabilized in the voltage generation circuit 1 as compared with the voltage generation circuit not including the additional circuit K1.

### <Practical Circuit of Voltage Generation Circuit>

Next, the practical circuit of the voltage generation circuit 1 will be described.

First, a case in which the voltage generation circuit 1 includes an operational amplifier terminal protection circuit will be described.

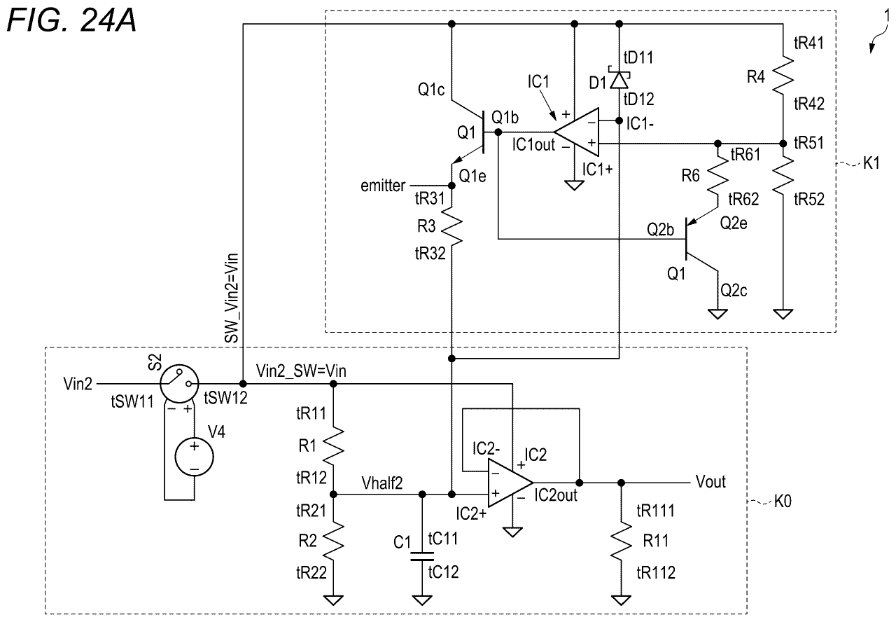

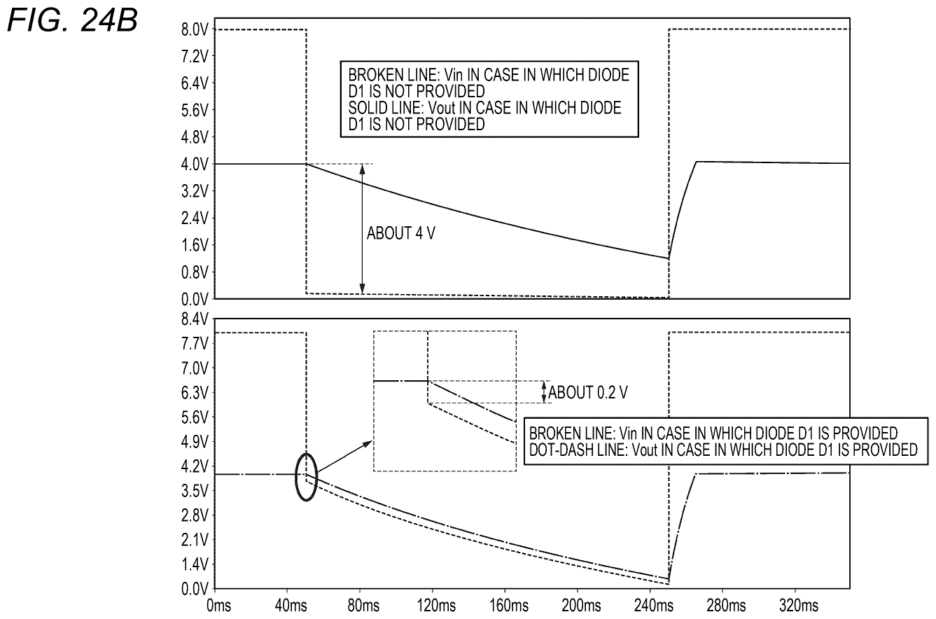

The case in which the voltage generation circuit 1 includes the operational amplifier terminal protection circuit will be described with reference to FIGS. 24A and 24B. FIG. 24A is a diagram illustrating a configuration of the voltage generation circuit 1. In FIG. 24A, the same components as those of the voltage generation circuit 1 illustrated in other drawings are denoted by the same reference numerals, and the description thereof will be omitted or simplified. FIG. 24B is a diagram illustrating the output voltage Vout. In FIG. 24B, horizontal axes represent time, and vertical axes represent voltage value.

The operational amplifier terminal protection circuit is a circuit that protects the terminals of the operational amplifier IC1, and is, for example, a Schottky barrier diode.

The voltage generation circuit 1 in FIG. 24A includes the voltage generation circuit 1 in FIG. 3B and further includes other circuit elements. Specifically, in the voltage generation circuit 1 in FIG. 24A, the additional circuit K1 includes a Schottky barrier diode D1. The Schottky barrier diode D1 is an example of a diode. The Schottky barrier diode D1 includes a cathode terminal tD11 and an anode terminal tD12. The cathode terminal tD11 is electrically connected to the terminal tR42, the collector terminal Q1c, and the like. The anode terminal tD12 is electrically connected to the inverting input terminal IC1−, the terminal tR32, the terminal tC11, and the like.

The voltage generation circuit 1 in FIG. 24A includes a resistor R11 and a power supply switch S2. The resistor R11 includes a terminal tR111 and a terminal tR112. The power supply switch S2 includes a terminal tSW11 and a terminal tSW12. The terminal tR111, the voltage output terminal Vout, the output terminal IC2out, and the inverting input terminal IC2− are electrically connected. The terminal tR112 is electrically connected to a ground potential. The terminal tSW12, the terminal tR11, a positive power supply terminal of the operational amplifier IC2, the collector terminal Q1c, and the cathode terminal tD11 are electrically connected. The terminal tSW11 and the voltage input terminal Vin are electrically connected.

It is assumed that the voltage generation circuit 1 does not include the Schottky barrier diode D1, and the power supply is rapidly turned off, that is, the input voltage at the voltage input terminal Vin rapidly decreases. In this case, the voltage at the inverting input terminal IC1− of the operational amplifier IC1 may be larger than the input voltage Vin of the voltage input terminal Vin. As illustrated in an upper graph in FIG. 24B, the voltage at the inverting input terminal IC1− may exceed a maximum rating of the operational amplifier IC1. For example, the output voltage Vout may become larger than the input voltage Vin by 4 V immediately after the power supply is turned off. In this case, the operational amplifier IC1 may fail. In contrast, since the voltage generation circuit 1 includes the Schottky barrier diode D1, it is possible to prevent the voltage at the inverting input terminal IC1− from exceeding the maximum rating of the operational amplifier IC1 as illustrated in a lower graph in FIG. 24B. For example, in the voltage generation circuit 1, the output voltage Vout can be made larger than the input voltage Vin by only 0.2 V even immediately after the power supply is turned off. The maximum rating of the operational amplifier IC1 may be, for example, 0.3 V or 0.7 V.

The Schottky barrier diode D1 may be another diode or may be replaced with another diode capable of avoiding exceeding the maximum rating of the operational amplifier IC1 as described above.

Next, a case in which the voltage generation circuit 1 includes a reset circuit will be described.

The reset circuit may be a microcomputer-controlled reset circuit that performs a reset based on a control signal from a microcomputer, an automatic reset circuit that performs a reset through an action of the circuit without using the control signal from the microcomputer, or the like. The reset circuit may be provided in the additional circuit K1.

The reset circuit is a circuit that temporarily rises the voltage VB at the point B in the additional circuit K1 to create a state in which the voltage VA at the point A is smaller than the voltage VB. Accordingly, even when the electric charge accumulated in the capacitor C1 remains, the voltage VA can be made smaller than the voltage VB, and the charging circuit KA of the additional circuit K1 can be operated early. That is, once the input voltage Vin is removed, the reset circuit supplies a voltage to the non-inverting input terminal IC1+ to control the voltage at the non-inverting input terminal IC1+ to be larger than the output voltage Vout.

First, a case in which the voltage generation circuit 1 includes the microcomputer-controlled reset circuit will be described.

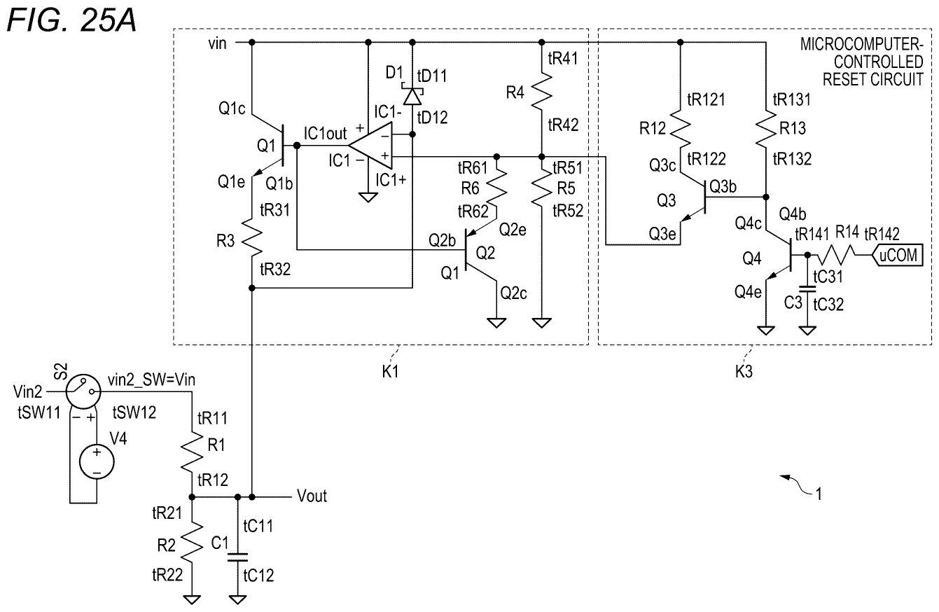

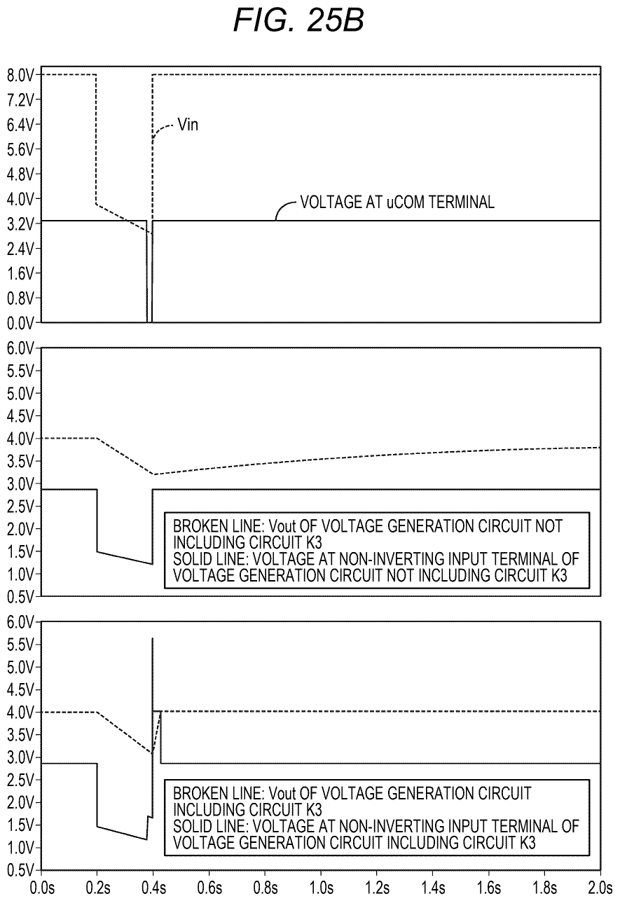

A case in which the voltage generation circuit 1 includes a microcomputer-controlled reset circuit K3 will be described with reference to FIGS. 25A and 25B. FIG. 25A is a diagram illustrating a configuration of the voltage generation circuit 1. In FIG. 25A, the same components as those of the voltage generation circuit 1 illustrated in other drawings are denoted by the same reference numerals, and the description thereof will be omitted or simplified. FIG. 25B is a diagram illustrating voltages at respective positions of the voltage generation circuit 1. In FIG. 25B, horizontal axes represent time, and vertical axes represent voltage value.

The microcomputer-controlled reset circuit K3 includes the resistor R12, a resistor R13, a resistor R14, a transistor Q3, a transistor Q4, and a capacitor C3.

The resistor R12 includes the terminal tR121 and the terminal tR122. The resistor R13 includes a terminal tR131 and a terminal tR 132. The resistor R14 includes a terminal tR141 and a terminal tR142. The transistor Q3 includes a base terminal Q3b, a collector terminal Q3c, and an emitter terminal Q3e. The transistor Q4 includes a base terminal Q4b, a collector terminal Q4c, and an emitter terminal Q4e. The capacitor C3 includes a terminal tC31 and a terminal tC32.

The terminal tR121, the terminal tR131, the terminal tR41, and the voltage input terminal Vin are electrically connected. The terminal tR 122 and the collector terminal Q3c are electrically connected. The terminal tR132, the base terminal Q3b, and the collector terminal Q3c are electrically connected. The emitter terminal Q3e, the terminal tR42, the terminal tR51, the terminal tR61, and the non-inverting input terminal IC1+ are electrically connected. The base terminal Q4b, the terminal tC31, and the terminal tR141 are electrically connected. The emitter terminal Q4e is electrically connected to a ground potential. The terminal tC32 is electrically connected to a ground potential. The terminal tR 142 is electrically connected to an uCOM terminal. The uCOM terminal indicates a terminal to which a signal is input. The uCOM terminal receives, for example, a signal from the microcomputer. Here, a reset control signal may be input. The reset control signal is an on-off control signal, that is, a signal that causes the High voltage and the Low voltage to change alternately.

In an upper graph in FIG. 25B, the input voltage Vin and a voltage at the uCOM terminal, that is, a voltage of the reset control signal of the voltage generation circuit 1 including the microcomputer-controlled reset circuit K3 are illustrated in time series. In a middle graph in FIG. 25B, the output voltage Vout and the voltage at the non-inverting input terminal IC1+ of the operational amplifier IC1 of the voltage generation circuit 1 not including the microcomputer-controlled reset circuit K3 are illustrated in time series. In a lower graph in FIG. 25B, the output voltage Vout and the voltage at the non-inverting input terminal IC1+ of the operational amplifier IC1 of the voltage generation circuit 1 including the microcomputer-controlled reset circuit K3 are illustrated in time series.

In the voltage generation circuit 1 not including the microcomputer-controlled reset circuit K3, the voltage may remain at the voltage output terminal Vout due to the electric charge accumulated in the capacitor C1 after the power supply is cut off, that is, after the input voltage Vin rapidly decreases. As a result, as illustrated in the middle graph in FIG. 25B, the output voltage Vout decreases once and then gradually increases. Therefore, even when the voltage generation circuit 1 is started up the next time, the voltage at the non-inverting input terminal IC1+ of the operational amplifier IC1 has a value smaller than the voltage value of the output voltage Vout. Therefore, the additional circuit K1 may not operate, and it may take time for the voltage generation circuit 1 to start up.

In contrast, in the voltage generation circuit 1, the additional circuit K1 can be reset by connecting the microcomputer-controlled reset circuit K3 to the additional circuit K1. Specifically, as illustrated in FIG. 25B, in the microcomputer-controlled reset circuit K3, the reset control signal is output from the uCOM terminal at the next startup, so that the transistor Q3 can be turned on when the power supply is turned on, that is, when the input voltage Vin is applied. Then, the voltage at the non-inverting input terminal IC1+ of the operational amplifier IC1 can be set to a value larger than an output voltage value, for example, 4 V by a combined resistor of the resistor R4 and the resistor R12. Accordingly, the additional circuit K1 can be quickly started up, and as illustrated in FIG. 25B, the output voltage Vout can be quickly set to a predetermined voltage, for example, 4 V immediately after the power supply is turned on. The reset control signal may also be used as a signal for controlling the on-off of the power supply switch S2.

Next, a case in which the voltage generation circuit 1 includes an automatic reset circuit K4 will be described.

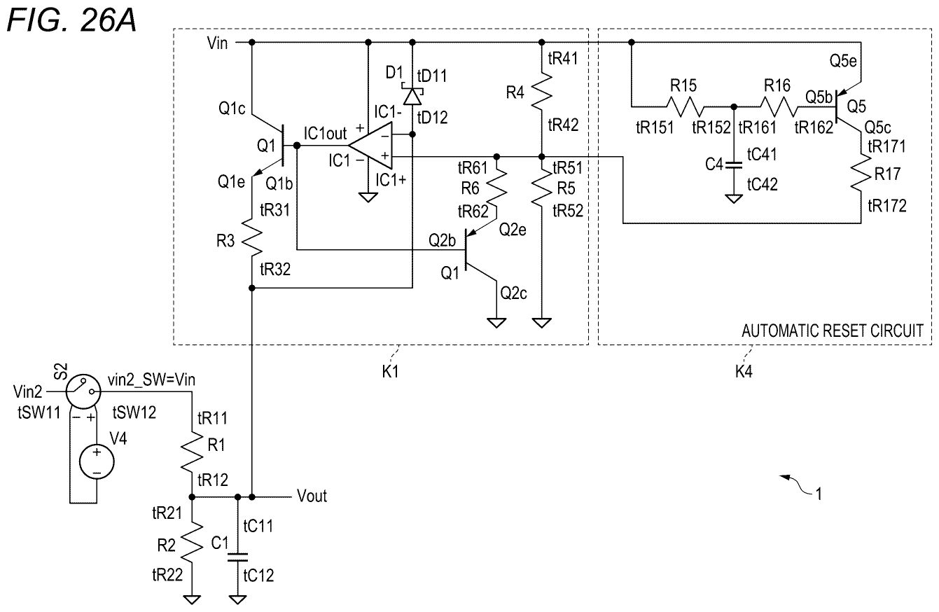

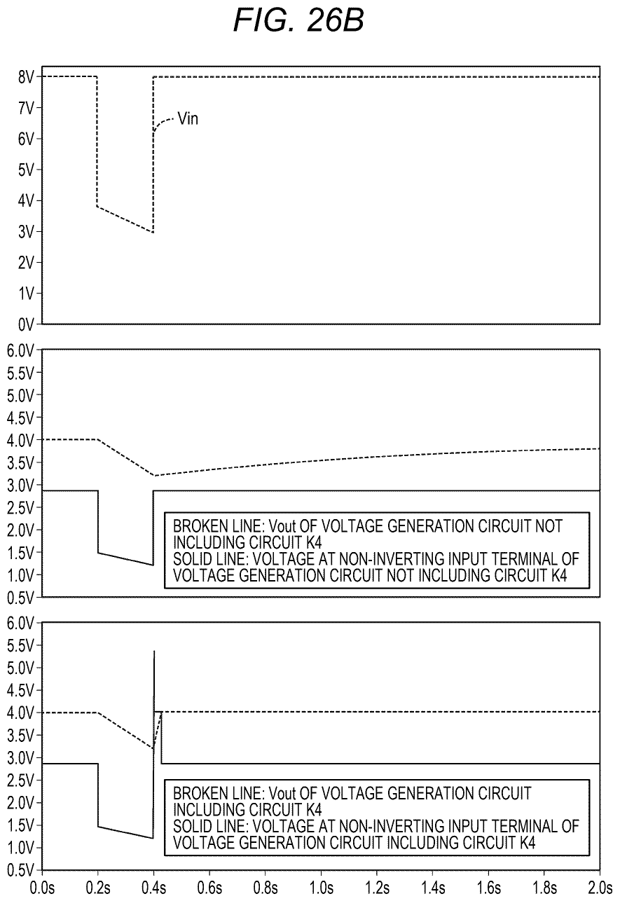

The case in which the voltage generation circuit 1 includes the automatic reset circuit K4 will be described with reference to FIGS. 26A and 26B. FIG. 26A is a diagram illustrating the voltage generation circuit 1. In FIG. 26A, the same components as those of the voltage generation circuit 1 illustrated in other drawings are denoted by the same reference numerals, and the description thereof will be omitted or simplified. FIG. 26B is a diagram illustrating voltages at respective positions of the voltage generation circuit 1. In FIG. 26B, horizontal axes represent time, and vertical axes represent voltage value.

The automatic reset circuit K4 includes a resistor R15, a resistor R16, a resistor R17, a transistor Q5, and a capacitor C4.

The resistor R15 includes a terminal tR151 and a terminal tR152. The resistor R16 includes a terminal tR 161 and a terminal tR 162. The resistor R17 includes a terminal tR 171 and a terminal tR172. The transistor Q5 includes a base terminal Q5b, a collector terminal Q5c, and an emitter terminal Q5e. The capacitor C4 includes a terminal tC41 and a terminal tC42.

The terminal tR151, the emitter terminal Q5e, the terminal tR41, and the voltage input terminal Vin are electrically connected. The terminal tR 152, the terminal tC41, and the terminal tR161 are electrically connected. The terminal tR162 and the base terminal Q5b are electrically connected. The terminal tC42 is electrically connected to a ground potential. The collector terminal Q5c and the terminal tR171 are electrically connected. The terminal tR172, the terminal tR42, the terminal tR51, the terminal tR61, and the non-inverting input terminal IC1+ are electrically connected.

In an upper graph in FIG. 26B, the input voltage Vin of the voltage generation circuit 1 including the automatic reset circuit K4 is illustrated in time series. In a middle graph in FIG. 26B, the output voltage Vout and the voltage at the non-inverting input terminal IC1+ of the operational amplifier IC1 of the voltage generation circuit 1 not including the automatic reset circuit K4 are illustrated in time series. In a lower graph in FIG. 26B, the output voltage Vout and the voltage at the non-inverting input terminal IC1+ of the operational amplifier IC1 of the voltage generation circuit 1 including the automatic reset circuit K4 are illustrated in time series.

In the voltage generation circuit 1 not including the automatic reset circuit K4, as illustrated in the middle graph in FIG. 26B, the output voltage Vout decreases once and then gradually increases. Therefore, even when the voltage generation circuit 1 is started up the next time, the voltage at the non-inverting input terminal IC1+ of the operational amplifier IC1 has a value smaller than the voltage value of the output voltage Vout. Therefore, the additional circuit K1 may not operate, and it may take time for the voltage generation circuit 1 to start up. A mechanism by which it takes time to start up is the same as that described for the voltage generation circuit 1 not including the microcomputer-controlled reset circuit K3.

In contrast, in the voltage generation circuit 1, the additional circuit K1 can be automatically reset by connecting the automatic reset circuit K4 to the additional circuit K1. Specifically, the automatic reset circuit K4 is configured such that the transistor Q5 is activated when the power supply of the voltage generation circuit 1 is turned on. As a result, as illustrated in FIG. 26B, the voltage at the non-inverting input terminal IC1+ can be set to a voltage larger than the output voltage value, for example, 4 V by a combined resistor of the resistor R17 and the resistor R4. Accordingly, the additional circuit K1 can be quickly started up, and as illustrated in FIG. 26B, the output voltage Vout can be quickly set to a predetermined voltage, for example, 4 V immediately after an input power supply is turned on.

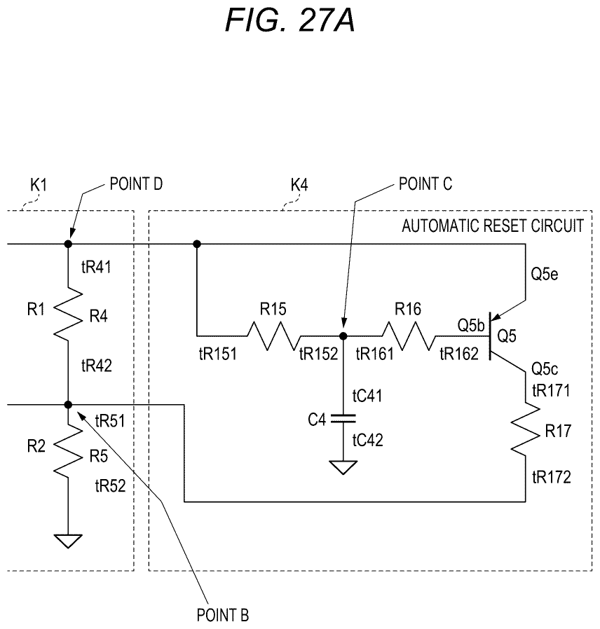

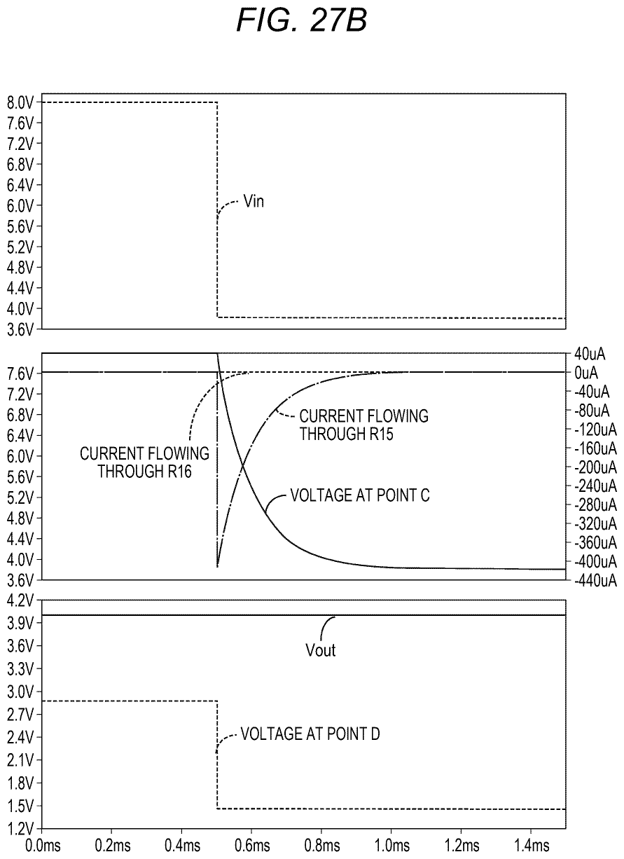

Operations at the time when the power supply is turned off in the case in which the voltage generation circuit 1 includes the automatic reset circuit K4 will be described with reference to FIGS. 27A and 27B. FIG. 27A is a diagram illustrating a circuit in which a part of the voltage generation circuit 1 in FIG. 26A is extracted. FIG. 27B is a diagram illustrating voltages and currents at respective positions of the voltage generation circuit 1. In FIG. 27B, horizontal axes represent time, and vertical axes represent voltage value or current value.

In an upper graph in FIG. 27B, the input voltage Vin of the voltage generation circuit 1 including the automatic reset circuit K4 is illustrated in time series. Here, it is particularly illustrated that the power supply is cut off and the input voltage Vin decreases from 8 V to less than 4 V, for example. In a middle graph in FIG. 27B, a voltage at a point C, a current flowing through the resistor R15, and a current flowing through the resistor R16 of the voltage generation circuit 1 including the automatic reset circuit K4 are illustrated in time series. The point C is a connection point between the terminal tR152, the terminal tC41, and the terminal tR161 in the voltage generation circuit 1 in FIG. 27A. In a lower graph in FIG. 27B, the output voltage Vout and the voltage at the non-inverting input terminal IC1+ of the operational amplifier IC1 of the voltage generation circuit 1 including the automatic reset circuit K4 are illustrated in time series.

When the power supply of the voltage generation circuit 1 is turned off, a voltage at a point D in FIG. 27A, that is, the input voltage Vin decreases, and an electric charge of the capacitor C4 is discharged via the resistor R15. As a result, the voltage at the point C in FIG. 27A decreases as illustrated in FIG. 27B. Accordingly, preparation for turning on the power supply of the voltage generation circuit 1 the next time is completed. The point D is a connection point of the terminal tR41, the terminal tR151, the emitter terminal Q5e, and the like in the voltage generation circuit 1 in FIG. 27A.

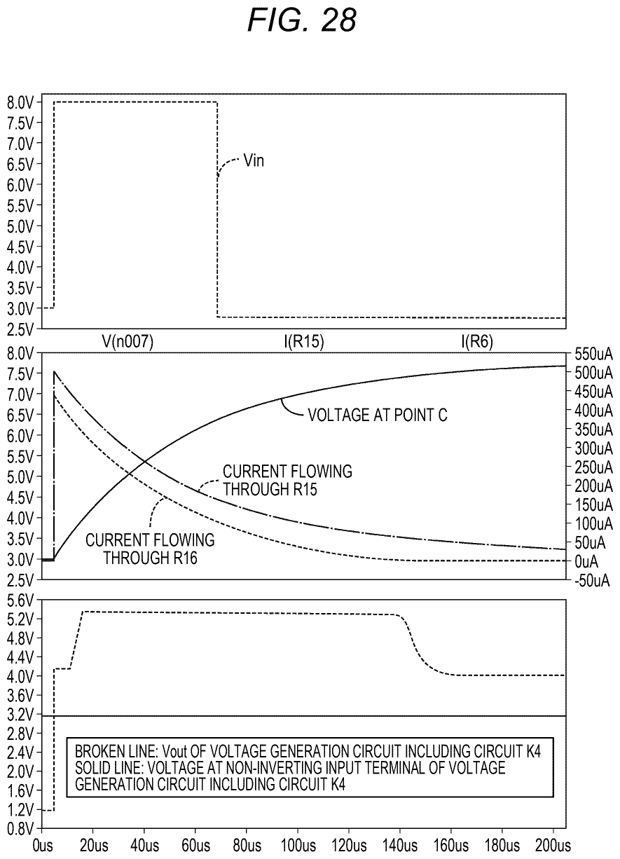

Operations at the time when the power supply is turned on in the case in which the voltage generation circuit 1 includes the automatic reset circuit K4 will be described with reference to FIGS. 27A and 28. FIG. 28 is a diagram illustrating voltages and currents at respective positions of the voltage generation circuit 1. In FIG. 28, horizontal axes represent time, and vertical axes represent voltage value or current value.

In an upper graph in FIG. 28, the input voltage Vin of the voltage generation circuit 1 including the automatic reset circuit K4 is illustrated in time series. Here, it is particularly illustrated that the power supply is turned on and the input voltage Vin rises from 3 V to 8 V, for example. In a middle graph in FIG. 28, the voltage at the point C, the current flowing through the resistor R15, and the current flowing through the resistor R16 of the voltage generation circuit 1 including the automatic reset circuit K4 are illustrated in time series. In a lower graph in FIG. 28, the output voltage Vout and the voltage at the non-inverting input terminal IC1+ of the operational amplifier IC1, that is, the voltage at the point B of the voltage generation circuit 1 including the automatic reset circuit K4 are illustrated in time series.

At a timing when the power supply of the voltage generation circuit 1 is turned on, as illustrated in FIG. 28, the voltage at the point D increases, and therefore, the capacitor C4 is charged with the electric charge via the resistor R15 and the resistor R16. While the current flows through the resistor R15, the transistor Q5 is turned on, and the voltage at the point B increases, so that the additional circuit K1 operates. That is, the automatic reset circuit K4 can make it easy to turn on the operational amplifier IC1 of the additional circuit K1, and can cause the operational amplifier IC1 to output the High voltage.

Next, a case in which the voltage generation circuit 1 includes a discharge circuit will be described. The discharge circuit may be a microcomputer-controlled discharge circuit that discharges based on a control signal from the microcomputer, an automatic discharge circuit that discharges through an action of the circuit without using the control signal from the microcomputer, or the like. The discharge circuit may be provided in the additional circuit K1.

The discharge circuit is a circuit that forcibly reduces the voltage at the voltage output terminal Vout to create a state in which the voltage VB is larger than the voltage VA at the point A corresponding to the voltage at the voltage output terminal Vout. Accordingly, even when the electric charge is accumulated in the capacitor C1, the electric charge is discharged, so that the voltage VA is smaller than the voltage VB. Therefore, the charging circuit KA of the additional circuit K1 can be operated early. Specifically, once the input voltage Vin is removed, the discharge circuit discharges the electric charge accumulated in the capacitor C1 to control the voltage at the non-inverting input terminal IC1+ to be larger than the output voltage Vout.

First, a case in which the voltage generation circuit 1 includes a microcomputer-controlled discharge circuit K5 will be described.

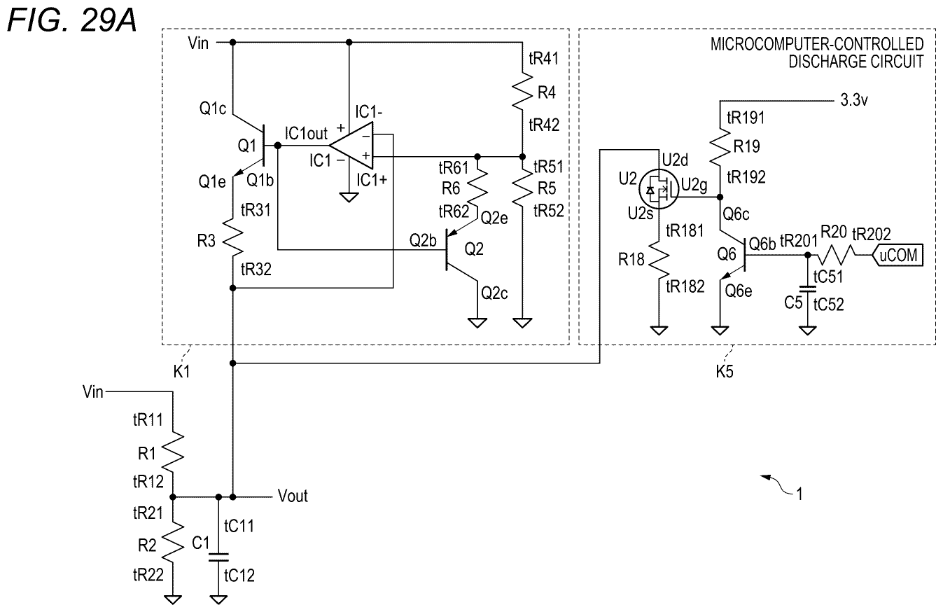

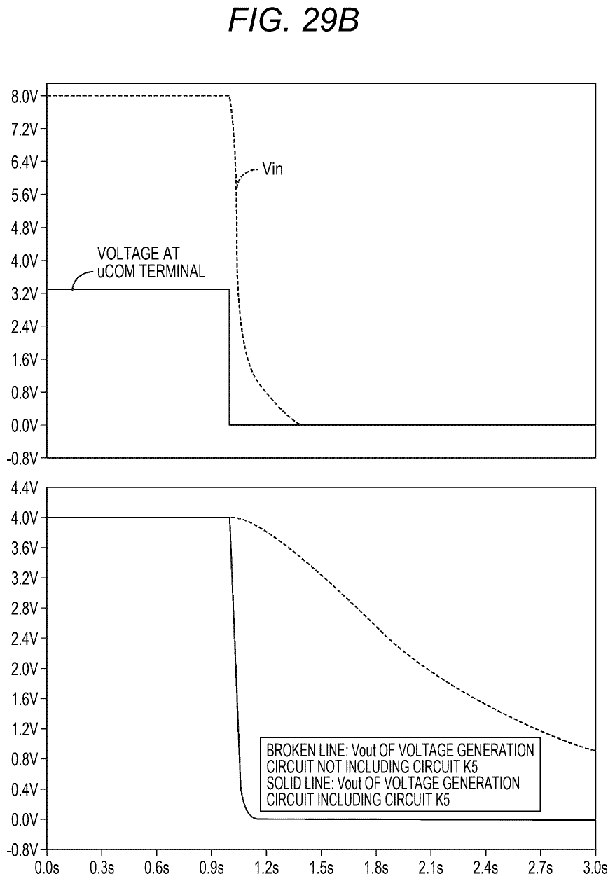

Operations in the case in which the voltage generation circuit 1 includes the microcomputer-controlled discharge circuit K5 will be described with reference to FIGS. 29A and 29B. FIG. 29A is a diagram illustrating a configuration of the voltage generation circuit 1. In FIG. 29A, the same components as those of the voltage generation circuit 1 illustrated in other drawings are denoted by the same reference numerals, and the description thereof will be omitted or simplified. FIG. 29B is a diagram illustrating voltages at respective positions of the voltage generation circuit 1. In FIG. 29B, horizontal axes represent time, and vertical axes represent voltage value.

The voltage generation circuit 1 in FIG. 29A includes the voltage generation circuit 1 in FIG. 3A and the microcomputer-controlled discharge circuit K5. The microcomputer-controlled discharge circuit K5 includes a resistor R18, a resistor R19, a resistor R20, the transistor U2, a transistor Q6, and a capacitor C5.

The resistor R18 includes a terminal tR181 and a terminal tR 182. The resistor R19 includes a terminal tR 191 and a terminal tR 192. The resistor R20 includes a terminal tR201 and a terminal tR202. The transistor U2 includes the gate terminal U2g, the source terminal U2s, and the drain terminal U2d. The transistor Q6 includes a base terminal Q6b, a collector terminal Q6c, and an emitter terminal Q6e. The capacitor C5 includes a terminal tC51 and a terminal tC52.

The terminal tR191 is electrically connected to a terminal to which a predetermined voltage, for example, a voltage of 3.3 V is applied. The terminal tR192, the gate terminal U2g, and the collector terminal Q6c are electrically connected. The terminal tR201, the terminal tC51, and the base terminal Q6b are electrically connected. The terminal tR202 and the uCOM terminal to which the microcomputer is connected are electrically connected. The uCOM terminal receives, for example, a discharge control signal from the microcomputer, specifically, an on-off control signal of the transistor Q6. The terminal tC52 is electrically connected to a ground potential. The emitter terminal Q6e is electrically connected to a ground potential. The drain terminal U2d, the terminal tR32, the terminal tR12, the terminal tR21, the terminal tC11, and the voltage output terminal Vout are electrically connected. The source terminal U2s and the terminal tR181 are electrically connected. The terminal tR182 is electrically connected to a ground potential.

In an upper graph in FIG. 29B, the input voltage Vin and the voltage at the uCOM terminal of the voltage generation circuit 1 including the microcomputer-controlled discharge circuit K5 are illustrated in time series. The voltage at the uCOM terminal reflects the on-off based on the control signal from the microcomputer. The control signal from the microcomputer may be the same signal as the control signal used for switching the power supply switch S2 described in another circuit, or may be a different signal. In a lower graph in FIG. 29B, the output voltage Vout of the voltage generation circuit 1 not including the microcomputer-controlled discharge circuit K5 and the output voltage Vout of the voltage generation circuit 1 including the microcomputer-controlled discharge circuit K5 are illustrated in time series.

In the voltage generation circuit 1 not including the microcomputer-controlled discharge circuit K5, it may take time for the voltage at the voltage output terminal Vout to decrease due to the electric charge accumulated in the capacitor C1 after the power supply is cut off, that is, after the input voltage Vin rapidly decreases. As a result, it may take time for the voltage generation circuit 1 to start up the next time.

In contrast, in the voltage generation circuit 1, the electric charge accumulated in the capacitor C1 can be discharged by operating the microcomputer-controlled discharge circuit K5 connected to the additional circuit K1. Accordingly, in the voltage generation circuit 1 including the microcomputer-controlled discharge circuit K5, the output voltage Vout can be quickly set to an off voltage, for example, 0 V when the power supply is cut off. The on-off control signal from the microcomputer may also be used as the signal for controlling the on-off of the power supply switch S2.

In the voltage generation circuit 1 in FIG. 29A, when the activation of an on-off control executed by the microcomputer is reversed, that is, when a voltage of the on-off control signal from the microcomputer is set to High when the input power supply is cut off, some of elements of the microcomputer-controlled discharge circuit K5 may be omitted. For example, the microcomputer-controlled discharge circuit K5 may include the transistor U2 and the resistor R18, and the gate terminal U2g may be electrically directly connected to the uCOM terminal. The same effect can also be obtained in this case.

Next, a case in which the voltage generation circuit 1 includes an automatic discharge circuit K6 will be described.

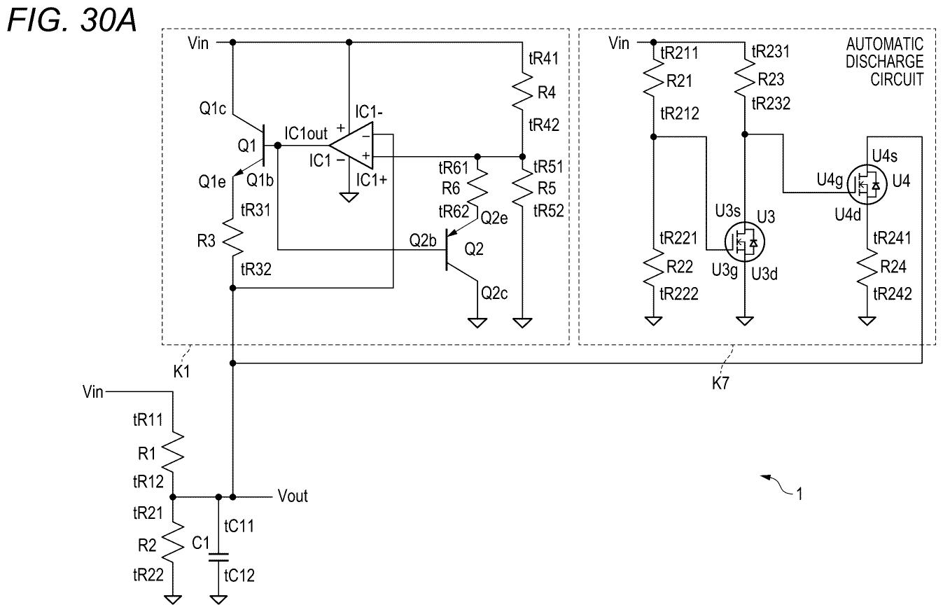

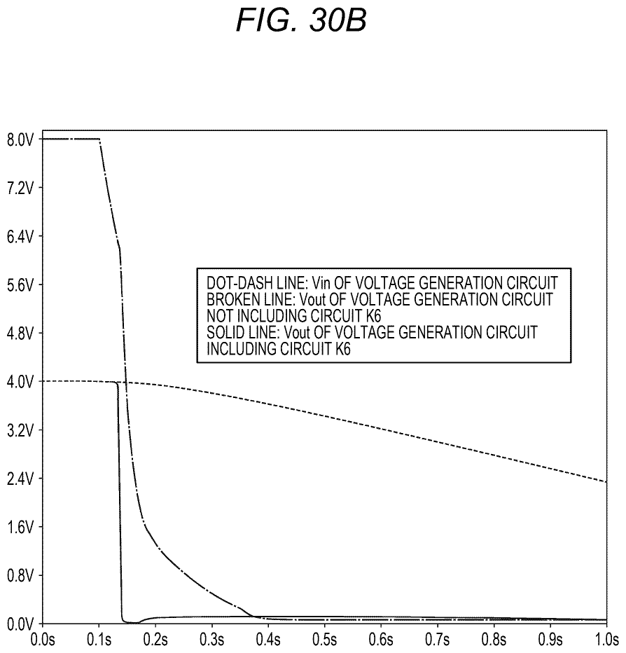

The case in which the voltage generation circuit 1 includes the automatic discharge circuit K6 will be described with reference to FIGS. 30A and 30B. FIG. 30A is a diagram illustrating a configuration of the voltage generation circuit 1. In FIG. 30A, the same components as those of the voltage generation circuit 1 illustrated in other drawings are denoted by the same reference numerals, and the description thereof will be omitted or simplified. FIG. 30B is a diagram illustrating the input voltage Vin and the output voltage Vout. In FIG. 30B, a horizontal axis represents time, and a vertical axis represents voltage value.

The voltage generation circuit 1 in FIG. 30A includes the voltage generation circuit 1 in FIG. 3A and the automatic discharge circuit K6. The automatic discharge circuit K6 includes a resistor R21, a resistor R22, a resistor R23, a resistor R24, a transistor U3, and a transistor U4.

The resistor R21 includes a terminal tR211 and a terminal tR212. The resistor R22 includes a terminal tR221 and a terminal tR222. The resistor R23 includes a terminal tR231 and a terminal tR232. The resistor R24 includes a terminal tR241 and a terminal tR242. The transistor U3 includes a gate terminal U3g, a source terminal U3s, and a drain terminal U3d. The transistor U4 includes a gate terminal U4g, a source terminal U4s, and a drain terminal U4d.

The terminal tR211, the terminal tR231, and the voltage input terminal Vin are electrically connected. The terminal tR212, the terminal tR221, and the gate terminal U3g are electrically connected. The terminal tR222 is electrically connected to a ground potential. The terminal tR232, the source terminal U3s, and the gate terminal U4g are electrically connected. The drain terminal U3d is electrically connected to the ground potential. The source terminal U4s, the terminal tR32, the terminal tR12, the terminal tR21, the terminal tC11, and the voltage output terminal Vout are electrically connected. The drain terminal U4d is electrically connected to a ground potential.

In a graph in FIG. 30B, the input voltage Vin of the voltage generation circuit 1 including the automatic discharge circuit K6, the output voltage Vout of the voltage generation circuit 1 not including the automatic discharge circuit K6, and the output voltage Vout of the voltage generation circuit 1 including the automatic discharge circuit K6 are illustrated in time series.

In the voltage generation circuit 1 not including the automatic discharge circuit K6, as illustrated in FIG. 30B, it takes time for the output voltage Vout to decrease, and it may take time for the voltage generation circuit 1 to start up the next time. A mechanism by which it takes time to start up is the same as that described for the voltage generation circuit 1 not including the microcomputer-controlled discharge circuit K5.

In contrast, in the voltage generation circuit 1, the electric charge accumulated in the capacitor C1 can be automatically discharged by operating the automatic discharge circuit K6 connected to the additional circuit K1. Specifically, in the voltage generation circuit 1, when the input voltage Vin is smaller than a voltage set based on the resistor R21 and the resistor R22, for example, 6.4 V in FIG. 30B, the automatic discharge circuit K6 can be automatically operated to discharge the electric charge. Accordingly, in the voltage generation circuit 1 including the automatic discharge circuit K6, the output voltage Vout can be quickly set to an off voltage, for example, 0 V when the power supply is cut off.

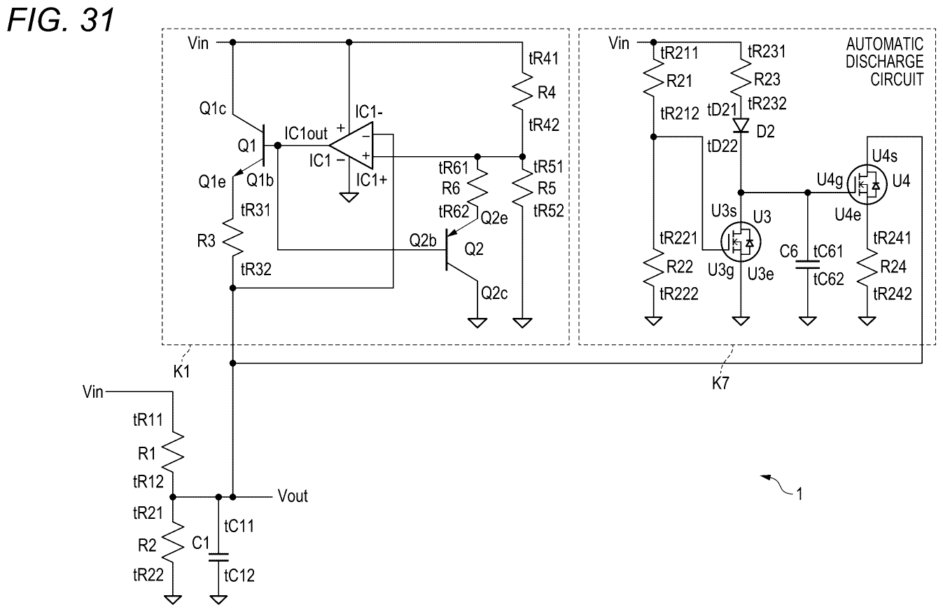

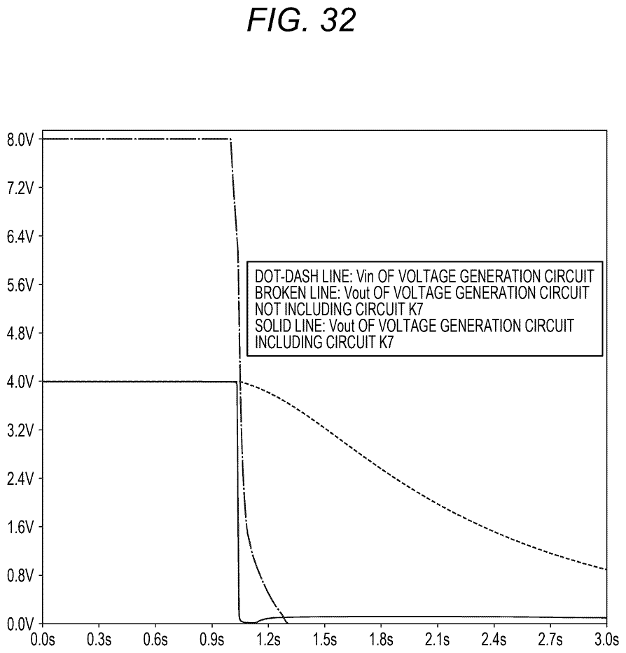

A case in which the voltage generation circuit 1 includes an automatic discharge circuit K7 will be described with reference to FIGS. 31 and 32. FIG. 31 is a diagram illustrating a configuration of the voltage generation circuit 1. In FIG. 31, the same components as those of the voltage generation circuit 1 illustrated in other drawings are denoted by the same reference numerals, and the description thereof will be omitted or simplified. FIG. 32 is a diagram illustrating the input voltage Vin and the output voltage Vout. In FIG. 32, a horizontal axis represents time, and a vertical axis represents voltage value.

The voltage generation circuit 1 in FIG. 31 includes the voltage generation circuit 1 in FIG. 3A and the automatic discharge circuit K7. The automatic discharge circuit K7 includes the resistor R21, the resistor R22, the resistor R23, the resistor R24, the transistor U3, the transistor U4, a capacitor C6, and a diode D2. That is, the automatic discharge circuit K7 additionally includes the capacitor C6 and the diode D2 as compared with the automatic discharge circuit K6 illustrated in FIG. 30A.

The capacitor C6 includes a terminal tC61 and a terminal tC61. The diode D2 includes a cathode terminal tD21 and an anode terminal tD22. The terminal tC61, the cathode terminal tD21, the source terminal U3s, and the gate terminal U4g are electrically connected. The terminal tC62 is electrically connected to a ground potential. The anode terminal tD22 and the terminal tR232 are electrically connected.

In a graph in FIG. 32, the input voltage Vin of the voltage generation circuit 1, the output voltage Vout of the voltage generation circuit 1 not including the automatic discharge circuit K7, and the output voltage Vout of the voltage generation circuit 1 including the automatic discharge circuit K7 are illustrated in time series.

In the voltage generation circuit 1 including the automatic discharge circuit K7 in FIG. 31, the transistor U4 can be kept on for a certain period of time by an action of the capacitor C6 as compared with the voltage generation circuit 1 including the automatic discharge circuit K6 in FIG. 30A. Accordingly, in the voltage generation circuit 1 including the automatic discharge circuit K7, the output voltage Vout can be easily fixed to a value close to 0 V, and therefore, the accuracy of generating the output voltage Vout when the power supply is cut off can be improved.

### <Application to Bias Power Supply Circuit>

Next, the application of the voltage generation circuit 1 to the bias power supply circuit K2 will be described.

FIG. 26A to FIG. 30A and FIG. 31 illustrate that various reset circuits and discharge circuits are provided on the voltage generation circuit 1 including the voltage divider circuit K0. Hereinafter, it will be illustrated that various reset circuits and discharge circuits are provided on the voltage generation circuit 1 including the bias power supply circuit K2, that is, the voltage generation circuit 1B.

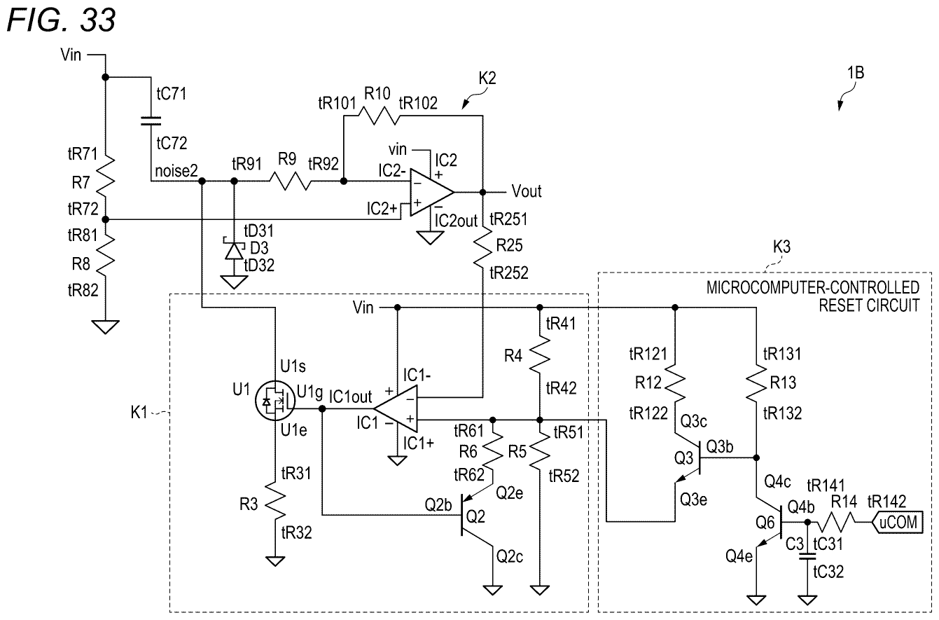

A case in which the voltage generation circuit 1B includes the microcomputer-controlled reset circuit K3 will be described with reference to FIG. 33. FIG. 33 is a diagram illustrating a configuration of the voltage generation circuit 1B. In FIG. 33, the same components as those of the voltage generation circuit 1 illustrated in other drawings are denoted by the same reference numerals, and the description thereof will be omitted or simplified.

The bias power supply circuit K2 may have the same configuration as the bias power supply circuit K2 illustrated in FIG. 8 or may have a different configuration. The bias power supply circuit K2 in FIG. 33 has the configuration of the bias power supply circuit K2 illustrated in FIG. 8, and additionally includes a Schottky barrier diode D3 and a resistor R25. The Schottky barrier diode D3 includes a cathode terminal tD31 and an anode terminal tD32. The resistor R25 includes a terminal tR251 and a terminal tR252. The cathode terminal tD31, the terminal tR91, the point Noise2, the terminal tC72, and the source terminal U1s are electrically connected. The anode terminal tD32 is electrically connected to a ground terminal. The terminal tR251, the terminal tR102, the output terminal IC12out, and the voltage output terminal Vout are electrically connected. The terminal tR252 and the inverting input terminal IC1− are electrically connected.

The same effect as that in the case in which the voltage generation circuit 1 includes the microcomputer-controlled reset circuit K3 can also be obtained in the case in which the voltage generation circuit 1B includes the microcomputer-controlled reset circuit K3.

Similarly, the same effect as that in the case in which the voltage generation circuit 1 includes the automatic reset circuit K4 can also be obtained in a case in which the voltage generation circuit 1B includes the automatic reset circuit K4.

Next, a case in which the voltage generation circuit 1B includes the microcomputer-controlled discharge circuit K5 will be described.

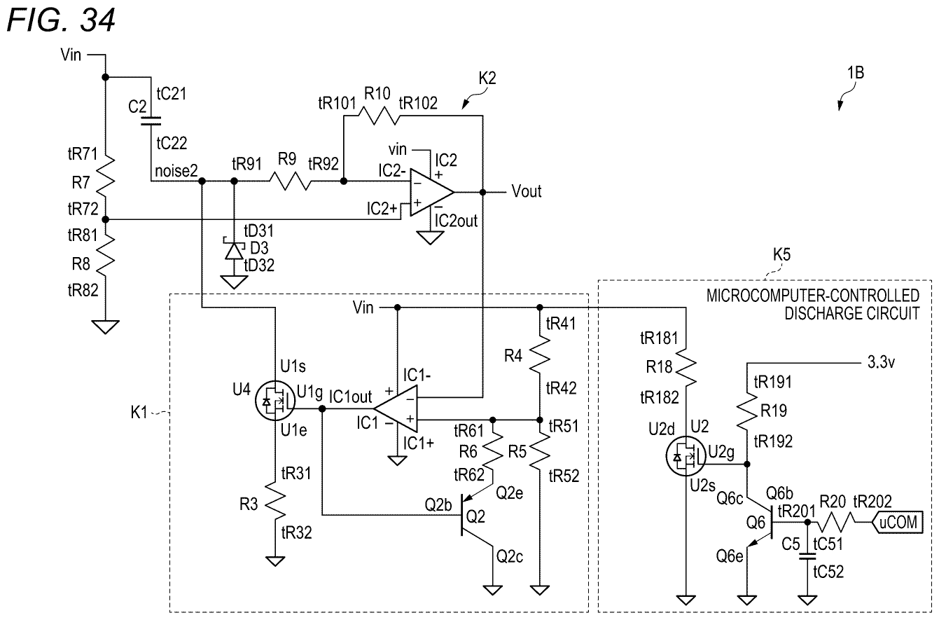

The case in which the voltage generation circuit 1B includes the microcomputer-controlled discharge circuit K5 will be described with reference to FIG. 34. FIG. 34 is a diagram illustrating a configuration of the voltage generation circuit 1B. In FIG. 34, the same components as those of the voltage generation circuit 1 illustrated in other drawings are denoted by the same reference numerals, and the description thereof will be omitted or simplified.

In the microcomputer-controlled discharge circuit K5 in FIG. 34, positions of the transistor U2 and the resistor R18 are reversed as compared with the microcomputer-controlled discharge circuit K5 in FIG. 29A. The terminal tR181 is electrically connected to the terminal tR41, the voltage input terminal Vin, and the like. The terminal tR182 is electrically connected to the drain terminal U2d. The source terminal U2s is electrically connected to a ground potential.

The same effect as that in the case in which the voltage generation circuit 1 includes the microcomputer-controlled discharge circuit K5 can also be obtained in the case in which the voltage generation circuit 1B includes the microcomputer-controlled discharge circuit K5.

Next, a case in which the voltage generation circuit 1B includes the microcomputer-controlled discharge circuit K5A will be described. The microcomputer-controlled discharge circuit K5A is a modification of the microcomputer-controlled discharge circuit K5.

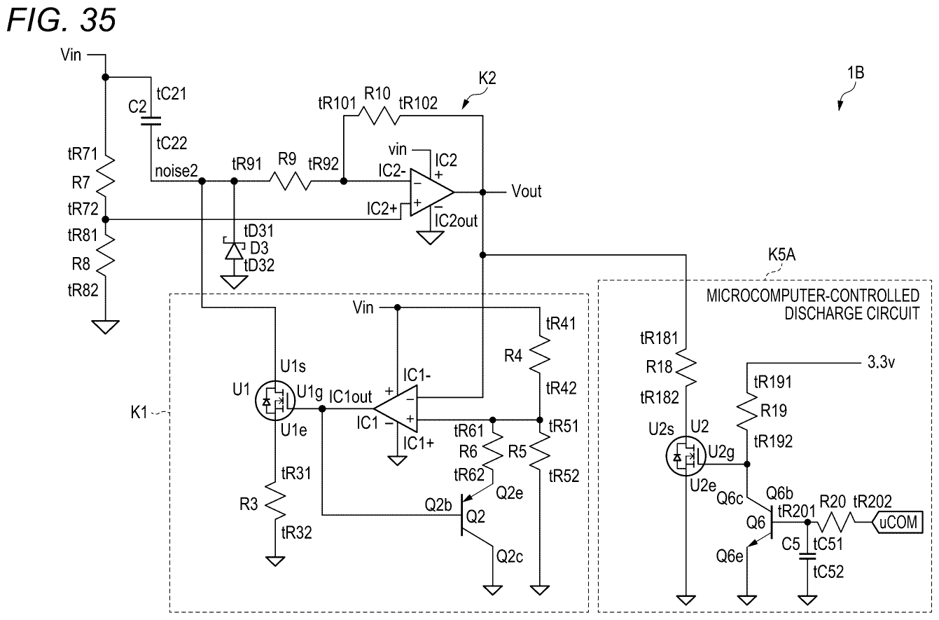

The case in which the voltage generation circuit 1B includes the microcomputer-controlled discharge circuit K5A will be described with reference to FIG. 35. FIG. 35 is a diagram illustrating a configuration of the voltage generation circuit 1B. In FIG. 35, the same components as those of the voltage generation circuit 1 illustrated in other drawings are denoted by the same reference numerals, and the description thereof will be omitted or simplified.

The microcomputer-controlled discharge circuit K5A in FIG. 35 is different from the microcomputer-controlled discharge circuit K5 in FIG. 34 in a connection destination of the terminal tR181. The terminal tR181 is electrically connected to the voltage output terminal Vout, the terminal tR102, the output terminal IC2out, the inverting input terminal IC1−, and the like.

The voltage generation circuit 1B including the microcomputer-controlled discharge circuit K5A illustrated in FIG. 35 has the same effect as the voltage generation circuit 1B including the microcomputer-controlled discharge circuit K5 illustrated in FIG. 34.

Next, a case in which the voltage generation circuit 1B includes an automatic discharge circuit K7A will be described. The automatic discharge circuit K7A is a modification of the automatic discharge circuit K7.

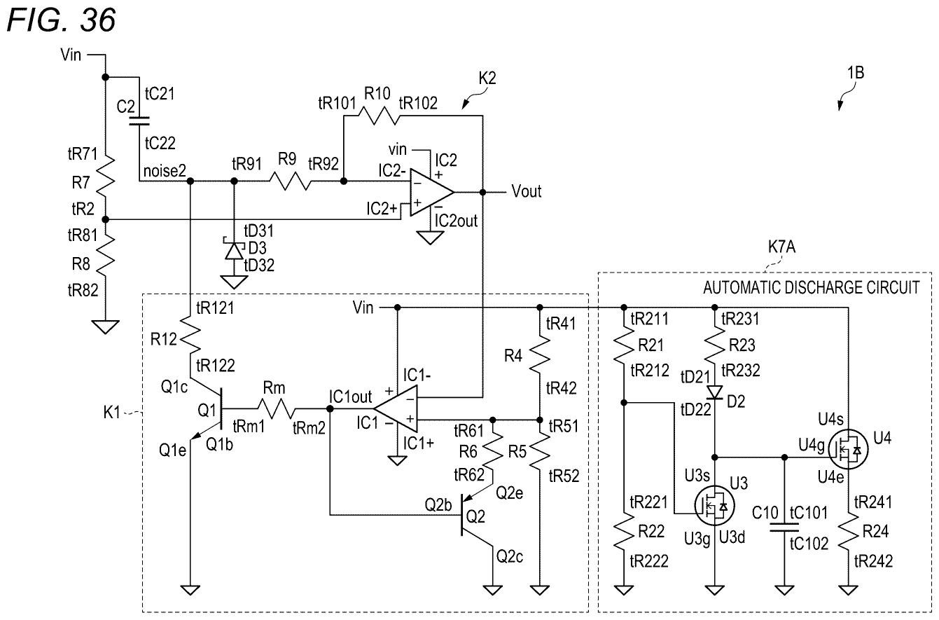

Then case in which the voltage generation circuit 1B includes the automatic discharge circuit K7A will be described with reference to FIG. 36. FIG. 36 is a diagram illustrating a configuration of the voltage generation circuit 1B. In FIG. 36, the same components as those of the voltage generation circuit 1 illustrated in other drawings are denoted by the same reference numerals, and the description thereof will be omitted or simplified.

The automatic discharge circuit K7A in FIG. 36 is different from the automatic discharge circuit K7 in FIG. 31 in a connection destination of the terminal tR211, the terminal tR231, and the source terminal U4s. Specifically, the terminal tR211, the terminal tR231, the source terminal U4s, the terminal tR41, and the voltage input terminal Vin are electrically connected.

The same effect as that in the case in which the voltage generation circuit 1 includes the automatic discharge circuit K7 can also be obtained in the case in which the voltage generation circuit 1B includes the automatic discharge circuit K7A. The automatic discharge circuit K7A is not connected to the operational amplifier IC2. If the automatic discharge circuit K7A is connected to an output terminal of the operational amplifier IC2, when the electric charge remaining in the capacitor C2 is discharged, the electric charge flows to ground through an input terminal and the output terminal of the operational amplifier IC2. That is, since the input terminal and the output terminal of the operational amplifier IC2 are shorted, a load may be applied to the operational amplifier IC2. On the other hand, in the present embodiment, since the automatic discharge circuit K7A is not connected to the operational amplifier IC2, the operational amplifier IC2 does not supply a discharge current. Accordingly, the load on the operational amplifier IC2 can be reduced.

Next, a case in which the voltage generation circuit 1B includes an automatic discharge circuit K7B will be described. The automatic discharge circuit K7B is a modification of the automatic discharge circuit K7.

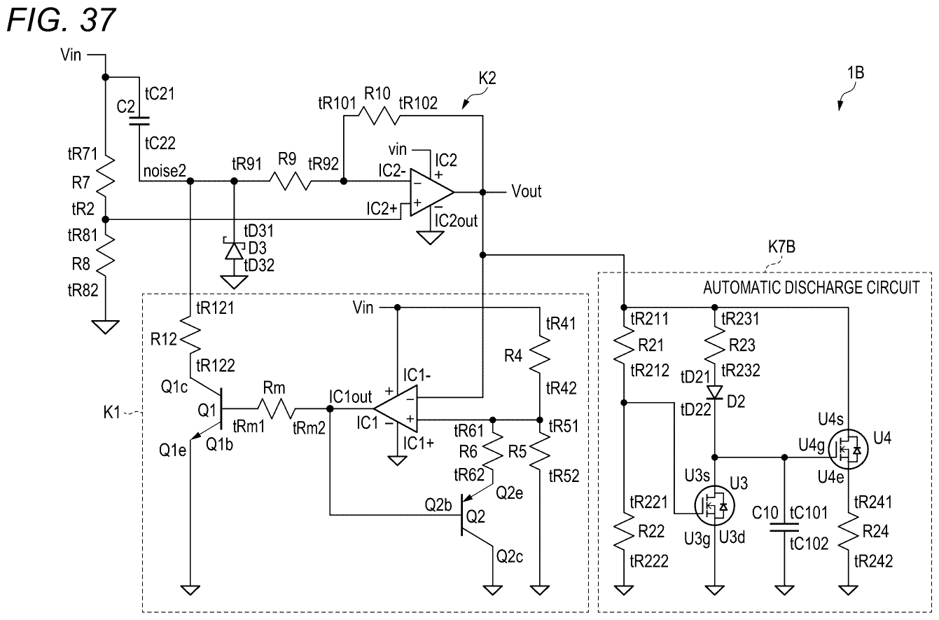

Then case in which the voltage generation circuit 1B includes the automatic discharge circuit K7B will be described with reference to FIG. 37. FIG. 37 is a diagram illustrating a configuration of the voltage generation circuit 1B. In FIG. 37, the same components as those of the voltage generation circuit 1 illustrated in other drawings are denoted by the same reference numerals, and the description thereof will be omitted or simplified.

The automatic discharge circuit K7B in FIG. 37 is different from the automatic discharge circuit K7 in FIG. 31 in a connection destination of the terminal tR211, the terminal tR231, and the source terminal U4s. Specifically, the terminal tR211, the terminal tR231, the source terminal U4s, the voltage output terminal Vout, the terminal tR102, the output terminal IC2out, and the inverting input terminal IC1− are electrically connected.

The same effect as that in the case in which the voltage generation circuit 1 includes the automatic discharge circuit K7 can also be obtained in the case in which the voltage generation circuit 1B includes the automatic discharge circuit K7B.

Next, the case in which the voltage generation circuit 1B includes the automatic discharge circuit K7A and the case in which the voltage generation circuit 1B includes the automatic discharge circuit K7B will be described in comparison.

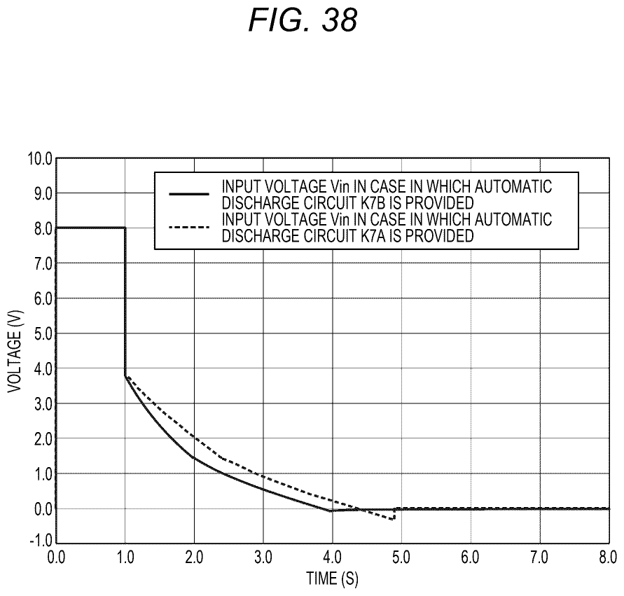

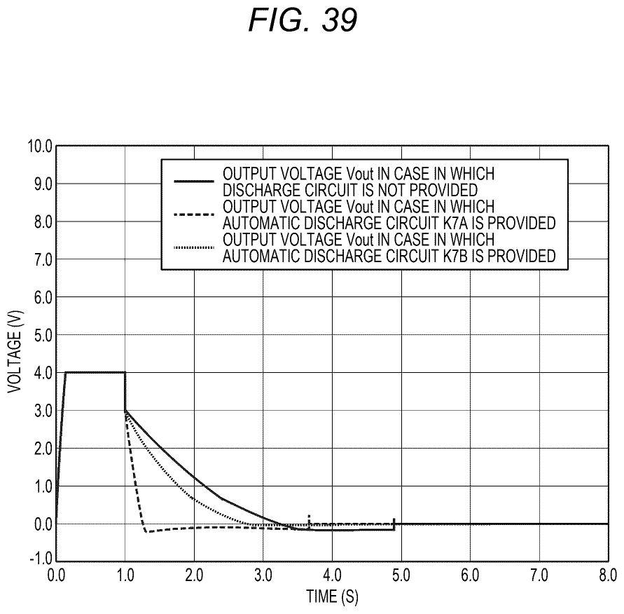

FIG. 38 is a diagram illustrating the input voltages Vin in the case in which the voltage generation circuit 1B includes the automatic discharge circuit K7A and the input voltages Vin in the case in which the voltage generation circuit 1B includes the automatic discharge circuit K7B. FIG. 39 is a diagram illustrating the output voltage Vout in the case in which the voltage generation circuit 1B includes the automatic discharge circuit K7A, the output voltage Vout in the case in which the voltage generation circuit 1B includes the automatic discharge circuit K7B, and the output voltage Vout in the case in which the voltage generation circuit 1B does not include the automatic discharge circuit.

As illustrated in FIG. 38, when the voltage generation circuit 1B includes the automatic discharge circuit K7A in FIG. 36, the input voltage Vin may become a negative value. Further, as illustrated in FIG. 39, the output voltage Vout may reach 0 V or less.

The automatic discharge circuit K7A in FIG. 36 is connected to the voltage input terminal Vin. When the voltage generation circuit 1B includes the automatic discharge circuit K7A, as illustrated in FIG. 39, a time required for the output voltage Vout to reach 0 V is the shortest. In addition, the load is less likely to be applied to the operational amplifier IC2.

The automatic discharge circuit K7B in FIG. 37 is connected to the voltage output terminal Vout. When the voltage generation circuit 1B includes the automatic discharge circuit K7B, the input voltage Vin and the output voltage Vout are less likely to have negative potentials. Even when the input voltage Vin and the output voltage Vout have the negative potentials, absolute values thereof are smaller than those in the case in which the voltage generation circuit 1B includes the automatic discharge circuit K7A. In an example illustrated in FIG. 39, the output voltage Vout in the case in which the voltage generation circuit 1B includes the automatic discharge circuit K7B reaches, for example, about −0.04 V. When the voltage generation circuit 1B includes the automatic discharge circuit K7B, a time required for the output voltage Vout to reach 0 V is shorter than when the voltage generation circuit 1B does not include the discharge circuit.

Although various embodiments are described above with reference to the drawings, it is needless to say that the present disclosure is not limited to such examples. It is apparent that a person skilled in the art can conceive of various modifications and alterations within the scope described in the claims, and it is understood that such modifications and alterations naturally fall within the technical scope of the present disclosure. In addition, the constituent elements in the above embodiments may be freely combined without departing from the scope of the invention.

### (Note)

The following techniques are disclosed based on the above-described description of the embodiments.

### (Technique 1)

A voltage generation circuit, including:
a voltage input terminal to which an input voltage is input;
a voltage output terminal from which an output voltage is output;
a first resistor including a first terminal electrically connected to the voltage input terminal and a second terminal electrically connected to the voltage output terminal;
a second resistor including a third terminal electrically connected to the second terminal and a fourth terminal;
a first capacitor electrically connected to one of the first terminal and the second terminal; and
a first circuit electrically connected to the one of the first terminal and the second terminal and including a charging circuit configured to charge the first capacitor.

The voltage input terminal is, for example, the voltage input terminal Vin. The voltage output terminal is, for example, the voltage output terminal Vout. The first terminal is, for example, the terminal tR11 or the terminal tR71. The second terminal is, for example, the terminal tR12 or the terminal tR72. The first resistor is, for example, the resistor R1 or the resistor R7. The third terminal is, for example, the terminal tR21 or the terminal tR81. The fourth terminal is, for example, the terminal tR22 or the terminal tR82. The second resistor is, for example, the resistor R2 or the resistor R8. The first capacitor is, for example, the capacitor C1 or the capacitor C2. The charging circuit is, for example, the charging circuit KA. The first circuit is, for example, the additional circuit K1. The voltage generation circuit is, for example, the voltage generation circuit 1 or the voltage generation circuit 1B.

Accordingly, in the voltage generation circuit, the first capacitor can be quickly charged by the charging circuit. Therefore, the output voltage can be quickly stabilized while reducing noise even when the output voltage is generated by using the first capacitor.

### (Technique 2)

The voltage generation circuit according to technique 1, in which
the first circuit includes:
   a third resistor including a fifth terminal electrically connected to the voltage input terminal and a sixth terminal; and
   a fourth resistor including a seventh terminal electrically connected to the sixth terminal and an eighth terminal, and
the charging circuit includes:
   an operational amplifier including an inverting input terminal electrically connected to the second terminal, a non-inverting input terminal electrically connected to the sixth terminal, and an output terminal;
   a first transistor including a first control terminal electrically connected to the output terminal, a first non-control terminal electrically connected to the voltage input terminal, and a second non-control terminal; and
   a fifth resistor including a ninth terminal electrically connected to the second non-control terminal and a tenth terminal electrically connected to the second terminal.

The fifth terminal is, for example, the terminal tR41. The sixth terminal is, for example, the terminal tR42. The third resistor is, for example, the resistor R4. The seventh terminal is, for example, the terminal tR51. The eighth terminal is, for example, the terminal tR52. The fourth resistor is, for example, the resistor R5. The inverting input terminal is, for example, the inverting input terminal IC1−. The non-inverting input terminal is, for example, the non-inverting input terminal IC1+. The output terminal is, for example, the output terminal IC1out. The operational amplifier is, for example, the operational amplifier IC1. The first control terminal is, for example, the base terminal Q1b or the gate terminal Ulb. The first non-control terminal is, for example, the collector terminal Q1c or the source terminal U1s. The third non-control terminal is, for example, the emitter terminal Q1e or the drain terminal U1d. The first transistor is, for example, the transistor Q1 or the transistor U1. The ninth terminal is, for example, the terminal tR31. The tenth terminal is, for example, the terminal tR32. The fifth resistor is, for example, the resistor R3.

Accordingly, in the voltage generation circuit, a voltage at the non-inverting input terminal can be increased before the output voltage, and the operational amplifier can be operated. Therefore, a charging current can be quickly supplied from the voltage input terminal via the transistor and the fifth resistor, and the first capacitor can be quickly charged.

### (Technique 3)

The voltage generation circuit according to technique 2, in which
the operational amplifier
   compares a non-inverting input voltage input to the non-inverting input terminal with an inverting input voltage input to the inverting input terminal,
   outputs, from the output terminal, an on voltage for turning on the first transistor when the non-inverting input voltage is smaller than the inverting input voltage, and
   outputs, from the output terminal, an off voltage for turning off the first transistor when the non-inverting input voltage is larger than the inverting input voltage.

Accordingly, in the voltage generation circuit, it is possible to switch between charging the first capacitor by turning on the first transistor and not charging the first capacitor by turning off the first transistor.

### (Technique 4)

The voltage generation circuit according to any one of techniques 1 to 3, in which
the first circuit includes a stop circuit configured to stop an operation of the charging circuit.

Accordingly, in the voltage generation circuit, the operation of the charging circuit can be stopped by the stop circuit.

### (Technique 5)

The voltage generation circuit according to technique 4, in which
the stop circuit includes:
   a sixth resistor including an eleventh terminal electrically connected to the sixth terminal and a twelfth terminal; and
   a second transistor including a second control terminal electrically connected to the output terminal, a third non-control terminal, and a fourth non-control terminal electrically connected to the twelfth terminal, and
the second transistor is turned on when the off voltage is input to the second control terminal.

The eleventh terminal is, for example, the terminal tR61. The twelfth terminal is, for example, the terminal tR62. The sixth resistor is, for example, the resistor R6. The second control terminal is, for example, the base terminal Q2b or the gate terminal U2g. The third non-control terminal is, for example, the collector terminal Q2c or the source terminal U2s. The fourth non-control terminal is the emitter terminal Q2e or the drain terminal U2d. The second transistor is, for example, the transistor Q2 or the transistor U2.

Accordingly, in the voltage generation circuit, when the output voltage becomes larger than the voltage at the non-inverting input terminal, the operational amplifier outputs the off voltage, thereby turning on the second transistor. Therefore, a state in which the output voltage is larger than the voltage at the non-inverting input terminal is maintained. Therefore, in the voltage generation circuit, even when, for example, the input voltage fluctuates, the charging circuit can be prevented from operating.

### (Technique 6)

The voltage generation circuit according to any one of techniques 2 to 5, in which
the first circuit includes a diode including a cathode terminal and an anode terminal,
the cathode terminal is electrically connected to the voltage input terminal, and
the anode terminal is electrically connected to the inverting input terminal.

The cathode terminal is, for example, the cathode terminal tD11. The anode terminal is, for example, the anode terminal tD12. The diode is, for example, the Schottky barrier diode D1.

Accordingly, in the voltage generation circuit, backflow can be prevented by the Schottky barrier diode D1, and the operational amplifier can be protected from breakdown even when the input voltage is rapidly removed, that is, is set to a Low voltage.

### (Technique 7)

The voltage generation circuit according to any one of techniques 2 to 6, in which
the first circuit includes a reset circuit, and
once the input voltage to the voltage input terminal is removed, the reset circuit supplies a voltage to the non-inverting input terminal to make a voltage at the non-inverting input terminal larger than the output voltage.

The reset circuit is, for example, the microcomputer-controlled reset circuit K3 or the automatic reset circuit K4.

Accordingly, in the voltage generation circuit, even when, for example, the output voltage becomes larger than the voltage at the non-inverting input terminal when the power supply is cut off, a state in which the voltage at the non-inverting input terminal is larger than the output voltage can be set, and the operational amplifier can be operated to output the on voltage. Therefore, in the voltage generation circuit, when the power supply is turned on again, the charging circuit can be quickly started up, so that the output voltage can be quickly stabilized.

### (Technique 8)

The voltage generation circuit according to any one of techniques 2 to 6, in which
the first circuit includes a discharge circuit, and
once the input voltage to the voltage input terminal is removed, the discharge circuit discharges an electric charge accumulated in the first capacitor to make a voltage at the non-inverting input terminal larger than the output voltage.

The discharge circuit is, for example, the microcomputer-controlled discharge circuit K5, the automatic discharge circuit K6, or the automatic discharge circuit K7.

Accordingly, in the voltage generation circuit, even when, for example, the output voltage becomes larger than the voltage at the non-inverting input terminal when the power supply is cut off, a state in which the voltage at the non-inverting input terminal is larger than the output voltage can be set, and the operational amplifier can be operated to output the on voltage. Therefore, in the voltage generation circuit, when the power supply is turned on again, the charging circuit can be quickly started up, so that the output voltage can be quickly stabilized.

### (Technique 9)

The voltage generation circuit according to any one of techniques 1 to 8, in which
the first capacitor and the first circuit are electrically connected to the first terminal.

Accordingly, in the voltage generation circuit, the output voltage can be quickly stabilized while reducing the noise even when the output voltage is generated by using the first capacitor electrically connected to the first terminal. Here, for example, the first terminal is the terminal tR71, and the first capacitor is the capacitor C2.

### (Technique 10)

The voltage generation circuit according to any one of techniques 1 to 8, in which
the first capacitor and the first circuit are electrically connected to the second terminal.

Accordingly, in the voltage generation circuit, the output voltage can be quickly stabilized while reducing the noise even when the output voltage is generated by using the first capacitor electrically connected to the second terminal. Here, for example, the second terminal is the tR12, and the first capacitor is the capacitor C1.

### INDUSTRIAL APPLICABILITY

The present disclosure is useful as, for example, a voltage generation circuit in which an output voltage can be quickly stabilized while reducing noise even when the output voltage is generated by using a capacitor.

### CROSS-REFERENCE TO RELATED APPLICATIONS

This application is based on and claims priority under 35 USC 119 from Japanese Patent Application No. 2024-157809 filed on Sep. 11, 2024, the contents of which are incorporated herein by reference.

What is claimed is:

1. A voltage generation circuit, comprising:
a voltage input terminal to which an input voltage is input;
a voltage output terminal from which an output voltage is output;
a first resistor including a first terminal electrically connected to the voltage input terminal and a second terminal electrically connected to the voltage output terminal;
a second resistor including a third terminal electrically connected to the second terminal and a fourth terminal;
a first capacitor electrically connected to one of the first terminal and the second terminal; and
a first circuit electrically connected to the one of the first terminal and the second terminal and including a charging circuit configured to charge the first capacitor.

2. The voltage generation circuit according to claim 1, wherein
the first circuit includes:
a third resistor including a fifth terminal electrically connected to the voltage input terminal and a sixth terminal; and
a fourth resistor including a seventh terminal electrically connected to the sixth terminal and an eighth terminal, and
the charging circuit includes:
an operational amplifier including an inverting input terminal electrically connected to the second terminal, a non-inverting input terminal electrically connected to the sixth terminal, and an output terminal;
a first transistor including a first control terminal electrically connected to the output terminal, a first non-control terminal electrically connected to the voltage input terminal, and a second non-control terminal; and
a fifth resistor including a ninth terminal electrically connected to the second non-control terminal and a tenth terminal electrically connected to the second terminal.

3. The voltage generation circuit according to claim 2, wherein
the operational amplifier
compares a non-inverting input voltage input to the non-inverting input terminal with an inverting input voltage input to the inverting input terminal,
outputs, from the output terminal, an on voltage for turning on the first transistor when the non-inverting input voltage is smaller than the inverting input voltage, and
outputs, from the output terminal, an off voltage for turning off the first transistor when the non-inverting input voltage is larger than the inverting input voltage.

4. The voltage generation circuit according to claim 3, wherein
the first circuit includes a stop circuit configured to stop an operation of the charging circuit.

5. The voltage generation circuit according to claim 4, wherein
the stop circuit includes:
a sixth resistor including an eleventh terminal electrically connected to the sixth terminal and a twelfth terminal; and
a second transistor including a second control terminal electrically connected to the output terminal, a third non-control terminal, and a fourth non-control terminal electrically connected to the twelfth terminal, and
the second transistor is turned on when the off voltage is input to the second control terminal.

6. The voltage generation circuit according to claim 2, wherein
the first circuit includes a diode including a cathode terminal and an anode terminal,
the cathode terminal is electrically connected to the voltage input terminal, and
the anode terminal is electrically connected to the inverting input terminal.

7. The voltage generation circuit according to claim 2, wherein
the first circuit includes a reset circuit, and
once the input voltage to the voltage input terminal is removed, the reset circuit supplies a voltage to the non-inverting input terminal to make a voltage at the non-inverting input terminal larger than the output voltage.

8. The voltage generation circuit according to claim 2, wherein
the first circuit includes a discharge circuit, and
once the input voltage to the voltage input terminal is removed, the discharge circuit discharges an electric charge accumulated in the first capacitor to make a voltage at the non-inverting input terminal larger than the output voltage.

9. The voltage generation circuit according to claim 1, wherein
the first capacitor and the first circuit are electrically connected to the first terminal.

10. The voltage generation circuit according to claim 1, wherein
the first capacitor and the first circuit are electrically connected to the second terminal.

11. The voltage generation circuit according to claim 7, wherein
the reset circuit is a microcomputer-controlled reset circuit that performs a reset based on a control signal from a microcomputer, or an automatic reset circuit that performs a reset through an action of the circuit.

12. The voltage generation circuit according to claim 8, wherein
the discharge circuit is a microcomputer-controlled discharge or an automatic discharge circuit.

13. The voltage generation circuit according to claim 8, wherein
the discharge circuit is connected to the voltage input terminal or the voltage output terminal.

14. The voltage generation circuit according to claim 2, further comprising:
an operational amplifier terminal protection circuit that protects the terminals of the operational amplifier, wherein
the operational amplifier terminal protection circuit includes a cathode terminal and an anode terminal,
the cathode terminal is electrically connected to the six terminal and the first non-control terminal, and
the anode terminal is electrically connected to the inverting input terminal and the tenth terminal.
